(19) United States
(12) Patent Application Publication
(10) Pub. No.: US 2026/0013380 A1
(43) Pub. Date: Jan. 8, 2026

(54) DISPLAY DEVICE INCLUDING DOUBLET LENS

(71) Applicant: SAMSUNG DISPLAY CO., LTD., YONGIN-SI (KR)

(72) Inventor: Ji Won LEE, Yongin-si (KR)

(21) Appl. No.: 19/249,541

(22) Filed: Jun. 25, 2025

(30) Foreign Application Priority Data
Jul. 4, 2024 (KR) 10-2024-0088070

(51) Int. Cl. H10K 59/80

(52) U.S. Cl. CPC H10K 59/879

(57) ABSTRACT

Provided are a display device and an electronic device. A display device includes, a display panel, a first polarizing film disposed on the display panel, a first phase retardation film disposed on the first polarizing film, a semi-transmissive reflective film disposed on the first phase retardation film, a first lens disposed on the semi-transmissive reflective film, a second phase retardation film disposed on the first lens, a second polarizing film disposed on the second phase retardation film, and a second lens disposed on the second polarizing film, wherein the first lens or the second lens is a doublet lens in which a first sub-lens and a second sub-lens are bonded.

### CROSS-REFERENCE TO RELATED APPLICATION

This application claims priority under 35 U.S.C. 119 from Korean Patent Application No. 10-2024-0088070 filed on Jul. 4, 2024, in the Korean Intellectual Property Office, the disclosure of which is herein incorporated by reference in its entirety.

### BACKGROUND

### 1. Technical Field

The present disclosure relates to a display device including a doublet lens and an electronic device including a display device having a doublet lens.

### 2. Discussion of Related Art

A head mounted display (HMD) is an image display device that may be worn on a user's head in the form of glasses, goggles, or helmets, and which may display an image having a focus at a close distance in front of the user's eyes. The head mounted display may display virtual reality (VR) or augmented reality (AR) environments.

The head mounted display may magnify an image displayed on a small display device by using a plurality of lenses, and may display the magnified image. Therefore, the display device applied to the head mounted display needs to provide high-resolution images, for example, images with a resolution of 3000 PPI (Pixels Per Inch) or higher. To this end, an organic light-emitting diode on silicon (OLEDoS), which is a high-resolution small organic light-emitting display device, may be used as the display device of the head mounted display. The OLEDOS may be an image display device in which an organic light-emitting diode (OLED) is disposed on a semiconductor wafer substrate including complementary metal oxide semiconductor (CMOS).

### SUMMARY

Aspects of the present disclosure provide a display device and an electronic device with a reduced thickness of an optical module.

Aspects of the present disclosure also provide a display device and an electronic device with improved light output efficiency.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, there is provided a display device including, a display panel configured to emit polarized light, a first phase retardation film disposed on the display panel, a semi-transmissive reflective film disposed on the first phase retardation film, a first lens disposed on the semi-transmissive reflective film, a second phase retardation film disposed on the first lens, a first polarizing film disposed on the second phase retardation film, and a second lens disposed on the first polarizing film, wherein the first lens or the second lens is a doublet lens in which a first sub-lens and a second sub-lens are bonded.

In an embodiment, the first lens is the doublet lens, the first lens comprises a first surface facing the display panel and a second surface facing away from the display panel, and average curvatures of the first surface and the second surface are different.

In an embodiment, the second lens is the doublet lens, the second lens comprises a first surface facing the display panel and a second surface facing away from the display panel, and average curvatures of the first surface and the second surface are different.

According to an aspect of the present disclosure, there is provided a display device including, a display panel, a first polarizing film disposed on the display panel, a first phase retardation film disposed on the first polarizing film, a semi-transmissive reflective film disposed on the first phase retardation film, a first lens disposed on the semi-transmissive reflective film, a second phase retardation film disposed on the first lens, a second polarizing film disposed on the second phase retardation film, and a second lens disposed on the second polarizing film, wherein the first lens or the second lens is a doublet lens in which a first sub-lens and a second sub-lens are bonded.

In an embodiment, the first lens is the doublet lens, the first lens comprises a first surface facing the display panel and a second surface facing away from the display panel, and average curvatures of the first surface and the second surface are different.

In an embodiment, the average curvature of the first surface is greater than the average curvature of the second surface.

In an embodiment, the first surface is an aspherical surface, and the second surface is a flat surface.

In an embodiment, the first lens is the doublet lens, the second lens comprises a third surface facing the display panel and a fourth surface facing away from the display panel, and average curvatures of the third surface and the fourth surface are different.

In an embodiment, the average curvature of the third surface is less than the average curvature of the fourth surface.

In an embodiment, the third surface and the fourth surface are aspherical surfaces.

In an embodiment, the first lens and the second lens contain plastic.

In an embodiment, the first lens is the doublet lens, the first sub-lens contains at least one of polymethylmethacrylate (PMMA)-based plastic or cyclic olefin copolymer (COC)-based plastic, the second sub-lens contains polycarbonate (PC)-based plastic, and the second lens contains at least one of polymethylmethacrylate (PMMA)-based plastic or cyclic olefin copolymer (COC)-based plastic.

In an embodiment, the second lens is the doublet lens, the first lens contains at least one of polymethylmethacrylate (PMMA)-based plastic or cyclic olefin copolymer (COC)-based plastic, the first sub-lens contains polycarbonate (PC)-based plastic, and the second sub-lens contains at least one of polymethylmethacrylate (PMMA)-based plastic or cyclic olefin copolymer (COC)-based plastic.

In an embodiment, the display panel comprises a plurality of pixels, a display element layer, and a plurality of lenses disposed on the display element layer and corresponding to the plurality of pixels, among the plurality of pixels, pixels positioned in a middle portion of the display panel are disposed in a straight line with corresponding first lenses of the plurality of lenses, and among the plurality of pixels, pixels positioned at an edge portion of the display panel are disposed to be shifted by a distance from corresponding second lenses of the plurality of lenses.

In an embodiment, the second lens is the doublet lens, the second lens comprises a first surface facing the display panel and a second surface facing away from the display panel, and average curvatures of the first surface and the second surface are different.

In an embodiment, the second lens is the doublet lens, the average curvature of the first surface is less than the average curvature of the second surface.

In an embodiment, the first surface is a flat surface, and the second surface is an aspherical surface.

In an embodiment, the second lens is the doublet lens, the first lens comprises a third surface facing the display panel and a fourth surface facing away from the display panel, and average curvatures of the third surface and the fourth surface are different.

In an embodiment, the average curvature of the third surface is greater than the average curvature of the fourth surface.

According to an aspect of the present disclosure, there is provided an electronic device include a display device, the display device including, a display panel, a first polarizing film disposed on the display panel, a first phase retardation film disposed on the first polarizing film, a semi-transmissive reflective film disposed on the first phase retardation film, a first lens disposed on the semi-transmissive reflective film, a second phase retardation film disposed on the first lens, a second polarizing film disposed on the second phase retardation film, and a second lens disposed on the second polarizing film, wherein the first lens or the second lens is a doublet lens in which a first sub-lens and a second sub-lens are bonded.

In accordance with the display device and an electronic device according to an embodiment of the present disclosure, the thickness of the optical module may be reduced.

In accordance with the display device and an electronic device according to an embodiment of the present disclosure, the light output efficiency may be improved.

However, effects according to embodiments of the present disclosure are not limited to those exemplified above and various other effects are incorporated herein.

### BRIEF DESCRIPTION OF THE DRAWINGS

The above and other aspects and features of the present disclosure will become more apparent by describing in detail embodiments thereof with reference to the attached drawings, in which:

FIG. 1 is an exploded perspective view showing a display device according to an embodiment;

FIG. 2 is a block diagram illustrating a display device according to an embodiment;

FIG. 3 is an equivalent circuit diagram of a first sub-pixel according to an embodiment;

FIG. 4 is a plan view illustrating an example of a display panel according to an embodiment;

FIG. 5 and FIG. 6 are plan views illustrating embodiments of the display area of FIG. 4;

FIG. 7 is a cross-sectional view illustrating an example of a display panel taken along line X1-X1′ of FIG. 5;

FIG. 8 is a schematic cross-sectional view illustrating a display element layer, lenses, and an optical module of a display device according to an embodiment;

FIG. 9 and FIG. 10 are cross-sectional views showing a display device according to an embodiment;

FIG. 11 is a schematic diagram illustrating the path and polarization state of light emitted from a display device according to an embodiment;

FIG. 12 and FIG. 13 are cross-sectional views showing a display device according to another embodiment;

FIG. 14 is an exploded perspective view illustrating a head mounted display according to an embodiment;

FIG. 15 is a perspective view showing an augmented reality content providing device according to an embodiment;

FIG. 16 is a rear exploded perspective view of the augmented reality content providing device of FIG. 15; and

FIG. 17 is a front exploded perspective view of the augmented reality content providing device of FIG. 15.

### DETAILED DESCRIPTION

The invention will now be described more fully hereinafter with reference to the accompanying drawings, in which embodiments of the disclosure are shown. Aspects of this disclosure may, however, be embodied in different forms and should not be construed as limited to embodiments set forth herein. Rather, embodiments are provided so that this disclosure will be thorough and complete, and will fully convey the scope of the invention to those skilled in the art.

It will also be understood that when a layer is referred to as being “on” another layer or substrate, it can be directly on the other layer or substrate, or intervening layers may also be present. The same reference numbers indicate the same components throughout the specification. In the attached figures, the thickness of layers and regions may be exaggerated for clarity.

Hereinafter, embodiments of the present disclosure will be described in detail with reference to the accompanying drawings.

According to an embodiment, a display device includes a pancake lens configuration including of a convex lens and an aspherical/spherical doublet lens with improved luminance and a reduced thickness.

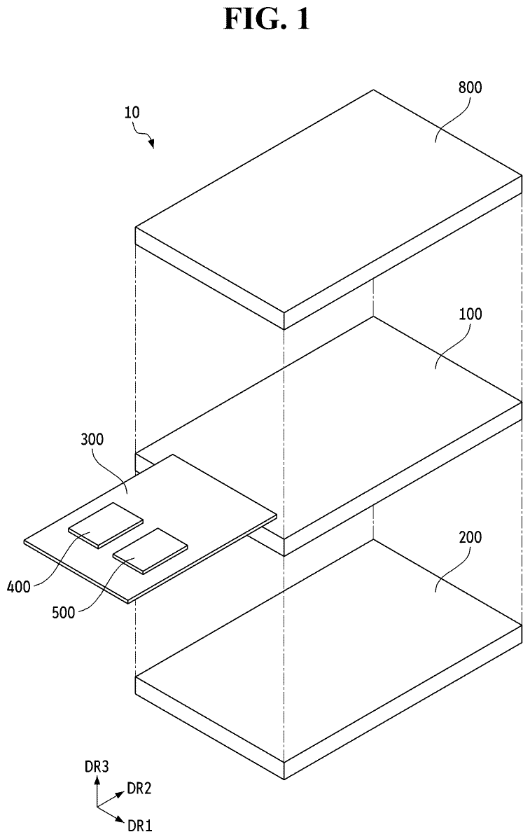

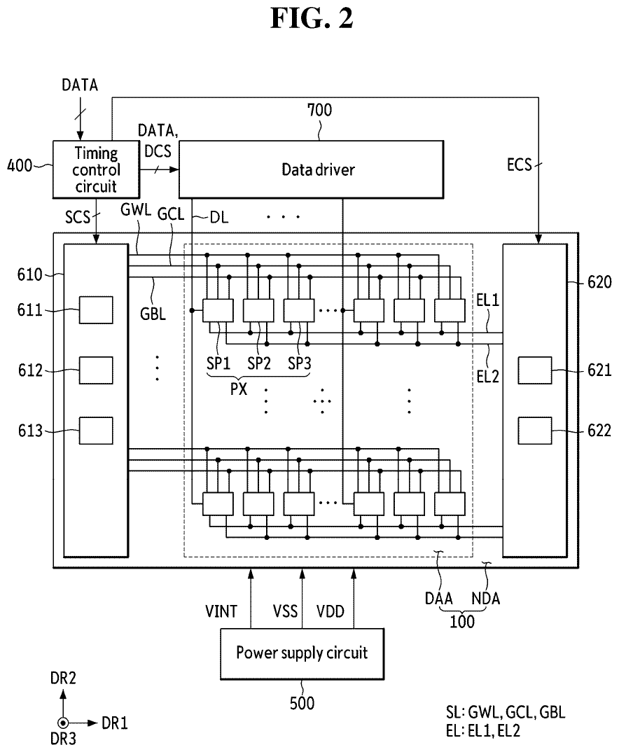

FIG. 1 is an exploded perspective view showing a display device according to an embodiment. FIG. 2 is a block diagram illustrating a display device according to an embodiment.

Referring to FIG. 1 and FIG. 2, a display device 10 according to an embodiment may be a device configured to display a moving image or a still image. The display device 10 according to an embodiment may be applied to portable electronic devices such as a mobile phone, a smartphone, a tablet personal computer, a mobile communication terminal, an electronic organizer, an electronic book, a portable multimedia player (PMP), a navigation system, an ultra-mobile PC (UMPC) or the like. For example, the display device 10 according to an embodiment may be applied as a display unit of a television, a laptop, a monitor, a billboard, or an Internet-of-Things (IoT) terminal. Alternatively, the display device 10 according to an embodiment may be applied to a smart watch, a watch phone, a head mounted display (HMD) for implementing virtual reality and augmented reality, or the like.

The display device 10 according to an embodiment may include a display panel 100, a heat dissipation layer 200, a circuit board 300, a timing control circuit 400, a power supply circuit 500, and an optical module 800.

The display panel 100 may have a planar shape similar to a quadrilateral shape. For example, the display panel 100 may have a planar shape similar to a quadrilateral shape, having a short side of a first direction DR1 and a long side of a second direction DR2 intersecting the first direction DR1. In the display panel 100, a corner where a short side in the first direction DR1 and a long side in the second direction DR2 meet may be right-angled or rounded with a predetermined curvature. The planar shape of the display panel 100 is not limited to a quadrilateral shape, and may be a shape similar to another polygonal shape, a circular shape, or an elliptical shape. The planar shape of the display device 10 may conform to the planar shape of the display panel 100, but the present disclosure is not limited thereto. For example, the display device 10 may have a curved shape.

In the illustrated figure, the first direction DR1 and the second direction DR2 cross each other as horizontal directions. For example, the first direction DR1 and the second direction DR2 may be orthogonal to each other and may define a plane. In addition, a third direction DR3 crosses the first direction DR1 and the second direction DR2, and may be, for example, perpendicular directions orthogonal to each other. Unless otherwise defined, in the present specification, directions indicated by arrows of the first to third directions DR1, DR2, and DR3 may be referred to as a side, and the opposite directions thereto may be referred to as an opposite side. Also, the terms “above,” “upper side,” “upper portion,” “top,” and “top surface,” as used herein, refer to a direction indicated by an arrow in the drawing in the third direction DR3 based on the drawings, and the terms “below,” “lower side,” “lower portion,” “bottom,” and “bottom surface,” as used herein, refer to a direction opposite to the direction indicated by the arrow in the third direction DR3 based on the drawings.

The display panel 100 may include a display area DAA, which may display an image and a non-display area NDA surrounding at least a portion of the display area DAA as shown in FIG. 2.

The display area DAA may include a plurality of pixels PX, a plurality of scan lines SL, a plurality of emission control lines EL, and a plurality of data lines DL.

The plurality of pixels PX may be arranged in a matrix form in the first direction DR1 and the second direction DR2. The plurality of scan lines SL and the plurality of emission control lines EL may extend in the first direction DR1, while being disposed in the second direction DR2. The plurality of data lines DL may extend in the second direction DR2, while being disposed in the first direction DR1.

The plurality of scan lines SL may include a plurality of write scan lines GWL, a plurality of control scan lines GCL, and a plurality of bias scan lines GBL. The plurality of emission control lines EL may include a plurality of first emission control lines EL1 and a plurality of second emission control lines EL2.

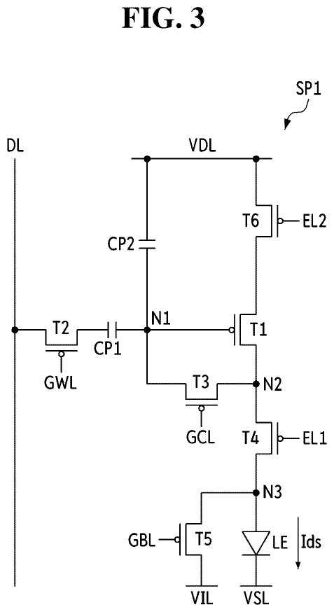

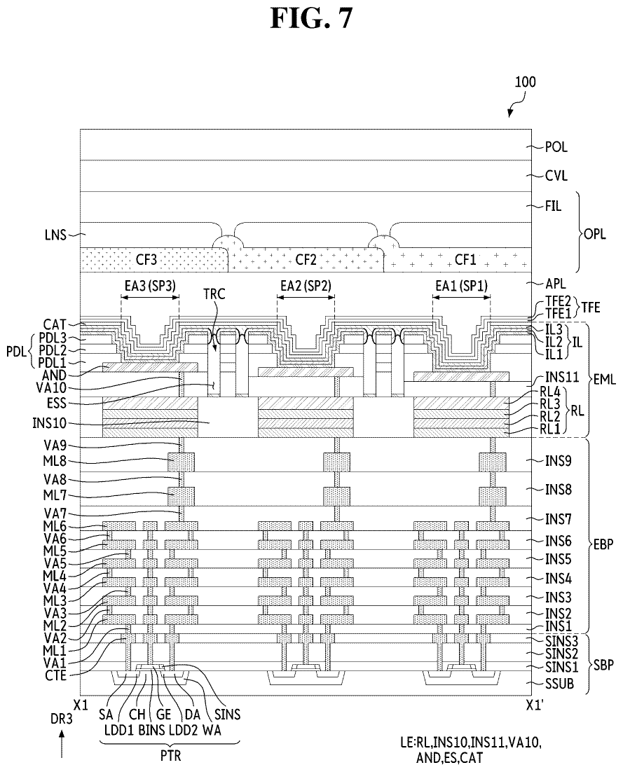

The plurality of pixels PX may include a plurality of sub-pixels SP1, SP2, and SP3. The plurality of sub-pixels SP1, SP2, and SP3 may include a plurality of pixel transistors as shown in FIG. 3, and the plurality of pixel transistors may be formed by a semiconductor process and disposed on a semiconductor substrate SSUB (see FIG. 7). For example, the plurality of pixel transistors of a data driver 700 may be formed of complementary metal oxide semiconductor (CMOS).

Each of the plurality of sub-pixels SP1, SP2, and SP3 may be connected to a write scan line GWL among the plurality of write scan lines GWL, a control scan line GCL among the plurality of control scan lines GCL, a bias scan line GBL among the plurality of bias scan lines GBL, a first emission control line EL1 among the plurality of first emission control lines EL1, a second emission control line EL2 among the plurality of second emission control lines EL2, and a data line DL among the plurality of data lines DL. Each of the plurality of sub-pixels SP1, SP2, and SP3 may receive a data voltage of the data line DL in response to a write scan signal of the write scan line GWL, and emit light from the light-emitting element according to the data voltage.

The non-display area NDA may include a scan driver 610, an emission driver 620, and the data driver 700.

The scan driver 610 may include a plurality of scan transistors, and the emission driver 620 may include a plurality of light-emitting transistors. The plurality of scan transistors and the plurality of light-emitting transistors may be formed through a semiconductor process, and disposed on the semiconductor substrate SSUB (see FIG. 7). For example, the plurality of scan transistors and the plurality of light-emitting transistors may be formed of CMOS. Although it is illustrated in FIG. 2 that the scan driver 610 is disposed on the left side of the display area DAA and the emission driver 620 is disposed on the right side of the display area DAA, the present disclosure is not limited thereto. For example, the scan driver 610 and the emission driver 620 may be disposed on both the left side and the right side of the display area DAA.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing control circuit 400. The write scan signal output unit 611 may generate write scan signals according to the scan timing control signal SCS of the timing control circuit 400 and output them sequentially to the write scan lines GWL. The control scan signal output unit 612 may generate control scan signals in response to the scan timing control signal SCS and sequentially output them to the control scan lines GCL. The bias scan signal output unit 613 may generate bias scan signals according to the scan timing control signal SCS and output them sequentially to bias scan lines GBL.

The emission driver 620 may include a first emission control driver 621 and a second emission control driver 622. Each of the first emission control driver 621 and the second emission control driver 622 may receive an emission timing control signal ECS from the timing control circuit 400. The first emission control driver 621 may generate first emission control signals according to the emission timing control signal ECS and sequentially output them to the first emission control lines EL1. The second emission control driver 622 may generate second emission control signals according to the emission timing control signal ECS and sequentially output them to the second emission control lines EL2.

The data driver 700 may include a plurality of data transistors, and the plurality of data transistors may be formed through a semiconductor process, and disposed on the semiconductor substrate SSUB (see FIG. 7). For example, the plurality of data transistors may be formed of CMOS.

The data driver 700 may receive digital video data DATA and a data timing control signal DCS from the timing control circuit 400. The data driver 700 may convert the digital video data DATA into analog data voltages according to the data timing control signal DCS and output the analog data voltages to the data lines DL. In this case, the sub-pixels SP1, SP2, and SP3 may be selected by the write scan signal of the scan driver 610, and data voltages may be supplied to the selected sub-pixels SP1, SP2, and SP3.

The heat dissipation layer 200 may overlap the display panel 100 in a third direction DR3, which is a thickness direction of the display panel 100. The heat dissipation layer 200 may be disposed on one surface of the display panel 100, for example, on the rear surface thereof. The heat dissipation layer 200 may serve to dissipate heat generated by the display panel 100. The heat dissipation layer 200 may include graphite or a metal layer having high thermal conductivity, such as silver (Ag), copper (Cu), or aluminum (Al).

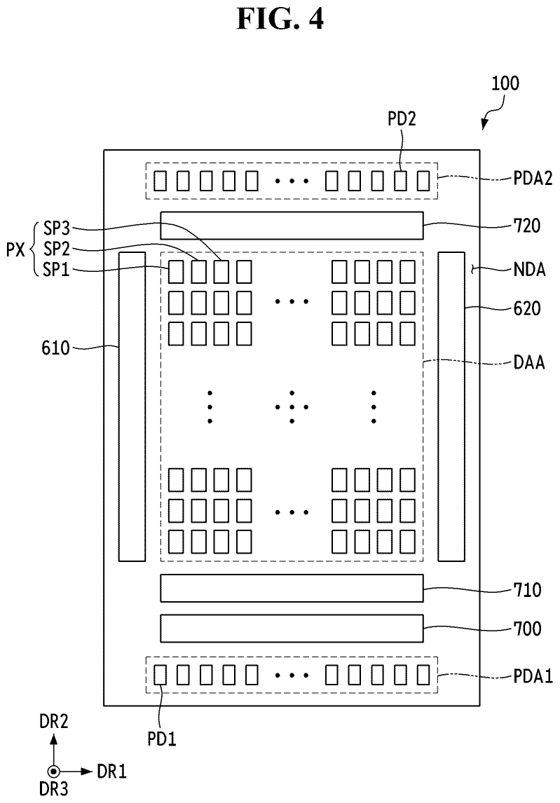

The circuit board 300 may be electrically connected to a plurality of first pads PD1 (see FIG. 4) of a first pad portion PDA1 (see FIG. 4) of the display panel 100 by using a conductive adhesive member such as an anisotropic conductive film. The circuit board 300 may be rigid or flexible. The circuit board 300 may be rigid and have a flat shape or a curved shape. The circuit board 300 may be a flexible printed circuit board with a flexible material, or a flexible film. Although the circuit board 300 is illustrated in FIG. 1 as being unfolded, the circuit board 300 may be bent. In this case, one end of the circuit board 300 may be disposed on the rear surface of the display panel 100 and/or the rear surface of the heat dissipation layer 200. One end of the circuit board 300 may be an opposite end of the other end of the circuit board 300 connected to the plurality of first pads PD1 (see FIG. 4) of the first pad portion PDA1 (see FIG. 4) of the display panel 100 by using a conductive adhesive member.

The timing control circuit 400 may receive digital video data DATA and timing signals inputted from the outside. The timing control circuit 400 may generate the scan timing control signal SCS, the emission timing control signal ECS, and the data timing control signal DCS for controlling the display panel 100 in response to the timing signals. The timing control circuit 400 may output the scan timing control signal SCS to the scan driver 610, and output the emission timing control signal ECS to the emission driver 620. The timing control circuit 400 may output the digital video data DATA and the data timing control signal DCS to the data driver 700.

The power supply circuit 500 may generate a plurality of panel driving voltages according to a power voltage from the outside. For example, the power supply circuit 500 may generate a first driving voltage VSS, a second driving voltage VDD, and a third driving voltage VINT and supply them to the display panel 100. The first driving voltage VSS, the second driving voltage VDD, and the third driving voltage VINT will be described later in conjunction with FIG. 3.

Each of the timing control circuit 400 and the power supply circuit 500 may be formed as an integrated circuit (IC) and attached to one surface of the circuit board 300. In this case, the scan timing control signal SCS, the emission timing control signal ECS, the digital video data DATA, and the data timing control signal DCS of the timing control circuit 400 may be supplied to the display panel 100 through the circuit board 300. Further, the first driving voltage VSS, the second driving voltage VDD, and the third driving voltage VINT of the power supply circuit 500 may be supplied to the display panel 100 through the circuit board 300.

Alternatively, each of the timing control circuit 400 and the power supply circuit 500 may be disposed in the non-display area NDA of the display panel 100, similarly to the scan driver 610, the emission driver 620, and the data driver 700. In this case, the timing control circuit 400 may include a plurality of timing transistors, and each power supply circuit 500 may include a plurality of power transistors. The plurality of timing transistors and the plurality of power transistors may be formed through a semiconductor process, and disposed on the semiconductor substrate SSUB (see FIG. 7). For example, the plurality of timing transistors and the plurality of power transistors may be formed of CMOS. Each of the timing control circuit 400 and the power supply circuit 500 may be disposed between the data driver 700 and the first pad portion PDA1 (see FIG. 4).

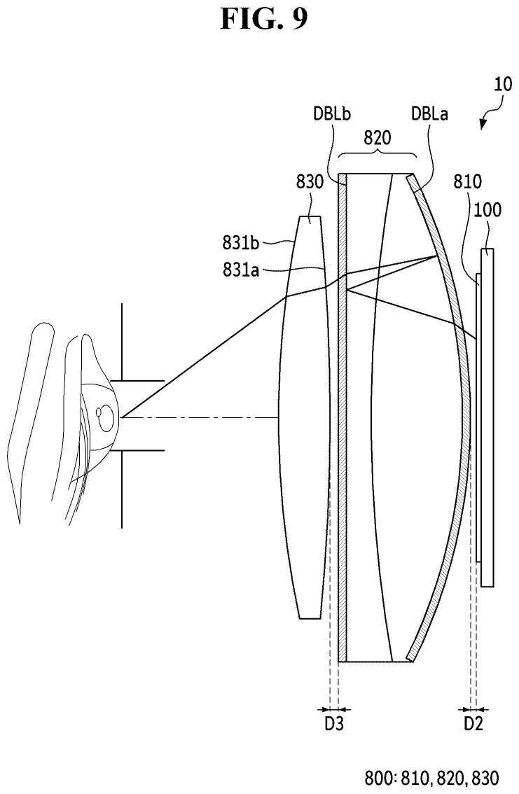

The optical module 800 may be disposed on the display panel 100. The optical module 800 may adjust the path and polarization state of light emitted from the display panel 100. The optical module 800 may implement folded optics system that folds an optical path. The optical module 800 is described with reference to FIG. 9 and the like.

FIG. 3 is an equivalent circuit diagram of a first sub-pixel according to an embodiment.

Referring to FIG. 3 in addition to FIGS. 1 and 2, the first sub-pixel SP1 may be connected to the write scan line GWL, the control scan line GCL, the bias scan line GBL, the first emission control line EL1, the second emission control line EL2, and the data line DL. Further, the first sub-pixel SP1 may be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied. That is, the first driving voltage line VSL may be a low potential voltage line, the second driving voltage line VDL may be a high potential voltage line, and the third driving voltage line VIL may be an initialization voltage line. In this case, the first driving voltage VSS may be lower than the third driving voltage VINT. The second driving voltage VDD may be higher than the third driving voltage VINT.

The first sub-pixel SP1 may include a plurality of transistors T1 to T6, a light-emitting element LE, a first capacitor CP1, and a second capacitor CP2.

The light-emitting element LE may emit light in response to a driving current (source-drain current) Ids flowing through the channel of a first transistor T1. A light emission amount of the light-emitting element LE may be proportional to the driving current. The light-emitting element LE may be disposed between a fourth transistor T4 and the first driving voltage line VSL. The first electrode of the light-emitting element LE may be connected to the drain electrode of the fourth transistor T4, and the second electrode thereof may be connected to the first driving voltage line VSL. The first electrode of the light-emitting element LE may be an anode electrode, and the second electrode of the light-emitting element LE may be a cathode electrode. The light-emitting element LE may be an organic light-emitting diode including a first electrode, a second electrode, and an organic light-emitting layer disposed between the first electrode and the second electrode, but the present disclosure is not limited thereto. For example, the light-emitting element LE may be an inorganic light-emitting element including a first electrode, a second electrode, and an inorganic semiconductor disposed between the first electrode and the second electrode, and the light-emitting element LE may be, e.g., a micro light-emitting diode.

The first transistor T1 may be a driving transistor that controls a driving current flowing between the source electrode and the drain electrode thereof according to a voltage applied to the gate electrode thereof. The first transistor T1 may include a gate electrode connected to a first node N1, a source electrode connected to the drain electrode of a sixth transistor T6, and a drain electrode connected to a second node N2.

A second transistor T2 may be disposed between an electrode of the first capacitor CP1 and the data line DL. The second transistor T2 may be turned on by the write scan signal of the write scan line GWL to connect the electrode of the first capacitor CP1 to the data line DL. Accordingly, the data voltage of the data line DL may be applied to the electrode of the first capacitor CP1. The second transistor T2 may include a gate electrode connected to the write scan line GWL, a source electrode connected to the data line DL, and a drain electrode connected to the electrode of the first capacitor CP1.

A third transistor T3 may be disposed between the first node N1 and the second node N2. The third transistor T3 may be turned on by the write control signal of the control scan line GCL to connect the first node N1 to the second node N2. For this reason, since the gate electrode and the drain electrode of the first transistor T1 are connected, the first transistor T1 may operate like a diode. The third transistor T3 may include a gate electrode connected to the control scan line GCL, a source electrode connected to the second node N2, and a drain electrode connected to the first node N1.

The fourth transistor T4 may be connected between the second node N2 and a third node N3. The fourth transistor T4 may be turned on by the first emission control signal of the first emission control line EL1 to connect the second node N2 to the third node N3. Accordingly, the driving current of the first transistor T1 may be supplied to the light-emitting element LE. The fourth transistor T4 may include a gate electrode connected to the first emission control line EL1, a source electrode connected to the second node N2, and a drain electrode connected to the third node N3.

A fifth transistor T5 may be disposed between the third node N3 and the third driving voltage line VIL. The fifth transistor T5 may be turned on by the bias scan signal of the bias scan line GBL to connect the third node N3 to the third driving voltage line VIL. Accordingly, the third driving voltage VINT of the third driving voltage line VIL may be applied to the first electrode of the light-emitting element LE. The fifth transistor T5 may include a gate electrode connected to the bias scan line GBL, a source electrode connected to the third node N3, and a drain electrode connected to the third driving voltage line VIL.

The sixth transistor T6 may be disposed between the source electrode of the first transistor T1 and the second driving voltage line VDL. The sixth transistor T6 may be turned on by the second emission control signal of the second emission control line EL2 to connect the source electrode of the first transistor T1 to the second driving voltage line VDL. Accordingly, the second driving voltage VDD of the second driving voltage line VDL may be applied to the source electrode of the first transistor T1. The sixth transistor T6 may include a gate electrode connected to the second emission control line EL2, a source electrode connected to the second driving voltage line VDL, and a drain electrode connected to the source electrode of the first transistor T1.

The first capacitor CP1 may be disposed between the first node N1 and the drain electrode of the second transistor T2. The first capacitor CP1 may include an electrode connected to the drain electrode of the second transistor T2 and the other electrode connected to the first node N1.

The second capacitor CP2 may be disposed between the gate electrode of the first transistor T1 and the second driving voltage line VDL. The second capacitor CP2 may include an electrode connected to the gate electrode of the first transistor T1 and the other electrode connected to the second driving voltage line VDL.

The first node N1 may be a junction between the gate electrode of the first transistor T1, the drain electrode of the third transistor T3, the other electrode of the first capacitor CP1, and the electrode of the second capacitor CP2. The second node N2 may be a junction between the drain electrode of the first transistor T1, the source electrode of the third transistor T3, and the source electrode of the fourth transistor T4. The third node N3 may be a junction between the drain electrode of the fourth transistor T4, the source electrode of the fifth transistor T5, and the first electrode of the light-emitting element LE.

Each of the first to sixth transistors T1 to T6 may be a metal-oxide-semiconductor field effect transistor (MOSFET). For example, each of the first to sixth transistors T1 to T6 may be a P-type MOSFET, but the present disclosure is not limited thereto. Each of the first to sixth transistors T1 to T6 may be an N-type MOSFET. Alternatively, some of the first to sixth transistors T1 to T6 may be P-type MOSFETs, and each of the remaining transistors may be an N-type MOSFET.

Although it is illustrated in FIG. 3 that the first sub-pixel SP1 includes six transistors T1 to T6 and two capacitors C1 and C2, the equivalent circuit diagram of the first sub-pixel SP1 is not limited to that shown in FIG. 3. For example, the number of the transistors and the number of the capacitors of the first sub-pixel SP1 may be changed independently.

Further, the equivalent circuit diagram of the second sub-pixel SP2 and the equivalent circuit diagram of the third sub-pixel SP3 may be substantially the same as the equivalent circuit diagram of the first sub-pixel SP1 described in conjunction with FIG. 3. Therefore, the description of the equivalent circuit diagram of the second sub-pixel SP2 and the equivalent circuit diagram of the third sub-pixel SP3 is not repeated in the present disclosure.

FIG. 4 is a plan view illustrating an example of a display panel according to an embodiment.

Referring to FIG. 4, the display area DAA of the display panel 100 according to an embodiment may include the plurality of pixels PX arranged in a matrix form. The non-display area NDA of the display panel 100 according to an embodiment may include the scan driver 610, the emission driver 620, the data driver 700, a first distribution circuit 710, a second distribution circuit 720, the first pad portion PDA1, and a second pad portion PDA2.

The scan driver 610 may be disposed on the first side of the display area DAA, and the emission driver 620 may be disposed on the second side of the display area DAA. For example, the scan driver 610 may be disposed on an opposite side of the display area DAA in the first direction DR1, and the emission driver 620 may be disposed on a side of the display area DAA in the first direction DR1. That is, the scan driver 610 may be disposed on the left side of the display area DAA, and the emission driver 620 may be disposed on the right side of the display area DAA. However, the present disclosure is not limited thereto, and the scan driver 610 and the emission driver 620 may be disposed on both the first side and the second side of the display area DAA.

The first pad portion PDA1 may include the plurality of first pads PD1 connected to pads or bumps of the circuit board 300 through a conductive adhesive member. The first pad portion PDA1 may be disposed on the third side of the display area DAA. For example, the first pad portion PDA1 may be disposed on an opposite side of the display area DAA in the second direction DR2. That is, the first pad portion PDA1 may be disposed on the lower side of the display area DAA.

The first pad portion PDA1 may be disposed outside the data driver 700 in the second direction DR2. That is, the first pad portion PDA1 may be disposed closer to the edge of the display panel 100 than the data driver 700.

The second pad portion PDA2 may include a plurality of second pads PD2 corresponding to inspection pads that test whether the display panel 100 operates normally. The plurality of second pads PD2 may be connected to a jig or a probe pin during an inspection process, or may be connected to a circuit board for inspection. The circuit board for inspection may be a printed circuit board made of a rigid material or a flexible printed circuit board made of a flexible material.

The first distribution circuit 710 may distribute data voltages applied through the first pad portion PDA1 to the plurality of data lines DL. For example, the first distribution circuit 710 may distribute the data voltages applied through one first pad PD1 of the first pad portion PDA1 to the P (P is a positive integer of 2 or more) data lines DL, and the number of the plurality of first pads PD1 may be reduced. The first distribution circuit 710 may be disposed on the third side of the display area DAA of the display panel 100. For example, the first distribution circuit 710 may be disposed on an opposite side of the display area DAA in the second direction DR2. That is, the first distribution circuit 710 may be disposed on the lower side of the display area DAA.

The second distribution circuit 720 may distribute signals applied through the second pad portion PDA2 to the scan driver 610, the emission driver 620, and the data lines DL. The second pad portion PDA2 and the second distribution circuit 720 may be configured to inspect the operation of each of the pixels PX in the display area DAA. The second distribution circuit 720 may be disposed on the fourth side of the display area DAA of the display panel 100. For example, the second distribution circuit 720 may be disposed on a side of the display area DAA in the second direction DR2. That is, the second distribution circuit 720 may be disposed on the upper side of the display area DAA.

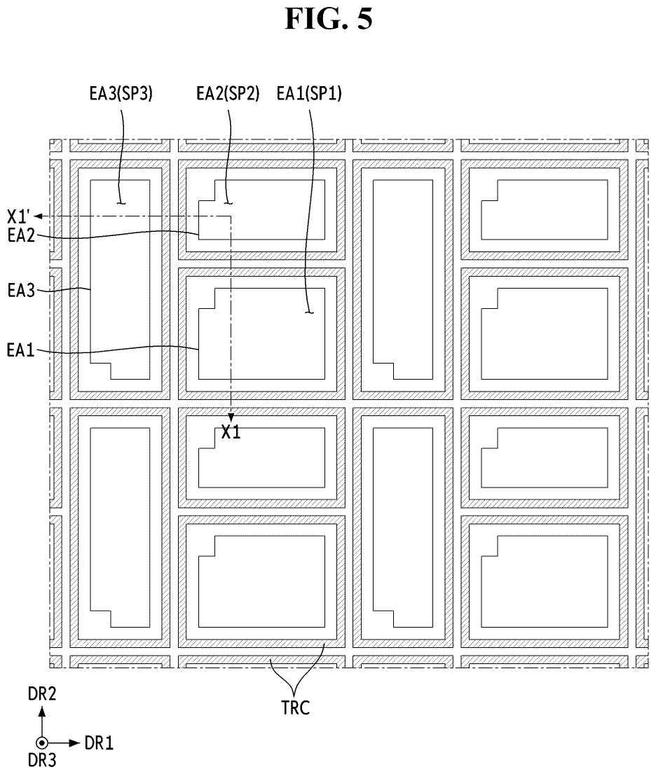

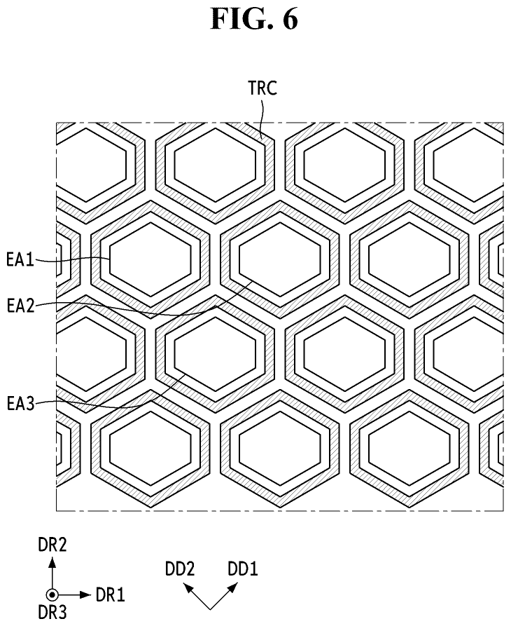

FIG. 5 and FIG. 6 are plan views illustrating embodiments of the display area of FIG. 4.

Referring to FIG. 5 and FIG. 6, each of the pixels PX may include the first emission area EA1 that is an emission area of the first sub-pixel SP1, the second emission area EA2 that is an emission area of the second sub-pixel SP2, and the third emission area EA3 that is an emission area of the third sub-pixel SP3.

In some embodiments, as shown in FIG. 5 and FIG. 6, the first emission area EA1, the second emission area EA2, and the third emission area EA3 may have, in plan view, a hexagonal shape formed of six straight lines, but the present disclosure is not limited thereto. The first emission area EA1, the second emission area EA2, and the third emission area EA3 may have a polygonal shape other than a hexagon, a circular shape, an elliptical shape, or an atypical shape in plan view.

In some embodiments, as shown in FIG. 5, a maximum length of the third emission area EA3 in the first direction DR1 may be smaller than a maximum length of the first emission area EA1 in the first direction DR1 and a maximum length of the second emission area EA2 in the first direction DR1. A maximum length of the first emission area EA1 in the first direction DR1 and a maximum length of the second emission area EA2 in the first direction DR1 may be substantially the same.

In some embodiments, as shown in FIG. 5, a maximum length of the third emission area EA3 in the second direction DR2 may be greater than a maximum length of the first emission area EA1 in the second direction DR2 and a maximum length of the second emission area EA2 in the second direction DR2. A maximum length of the first emission area EA1 in the second direction DR2 may be greater than a maximum length of the second emission area EA2 in the second direction DR2.

In an embodiment, as shown in FIG. 5, the first emission area EA1 and the second emission area EA2 in each of the plurality of pixels PX may be adjacent to each other in the second direction DR2. The first emission area EA1 and the third emission area EA3 may be adjacent to each other in the first direction DR1. The second emission area EA2 and the third emission area EA3 may be adjacent to each other in the first direction DR1. The area of the first emission area EA1, the area of the second emission area EA2, and the area of the third emission area EA3 may be different.

In another embodiment, as shown in FIG. 6, in each of the plurality of pixels PX, the first emission area EA1 and the second emission area EA2 may be adjacent to each other in the first direction DR1, but the second emission area EA2 and the third emission area EA3 may be adjacent to each other in a first diagonal direction DD1, and the first emission area EA1 and the third emission area EA3 may be adjacent to each other in a second diagonal direction DD2.

In the illustrated drawing, the first diagonal direction DD1 intersects each of the first direction DR1 and the second direction DR2 as horizontal directions. For example, the first diagonal direction DD1 may be a direction inclined by about 45 degrees with respect to the first direction DR1 and the second direction DR2, but the present disclosure is not limited thereto. The second diagonal direction DD2 intersects each of the first direction DR1 and the second direction DR2 as horizontal directions. For example, the second diagonal direction DD2 may be a direction inclined by about 45 degrees with respect to the opposite direction of the first direction DR1 and the second direction DR2, but the present disclosure is not limited thereto. The second diagonal direction DD2 may be a direction perpendicular to the first diagonal direction DD1.

The first emission area EA1 may emit light of a first color, the second emission area EA2 may emit light of a second color, and the third emission area EA3 may emit light of a third color. Here, the light of the first color may be light of a red wavelength band, the light of the second color may be light of a green wavelength band, and the light of the third color may be light of a blue wavelength band. For example, the blue wavelength band may be a wavelength band of light whose main peak wavelength is in the range of about 370 nanometers (nm) to about 460 nm, the green wavelength band may be a wavelength band of light whose main peak wavelength is in the range of about 480 nm to about 560 nm, and the red wavelength band may be a wavelength band of light whose main peak wavelength is in the range of about 600 nm to about 750 nm.

It is exemplified in FIG. 5 and FIG. 6 that each of the plurality of pixels PX includes three emission areas EA1, EA2, and EA3, but the present disclosure is not limited thereto. That is, each of the plurality of pixels PX may include four or more emission areas.

In addition, the shape and disposition of the emission areas of the plurality of pixels PX are not limited to those illustrated in FIG. 5 and FIG. 6. For example, the emission areas of the plurality of pixels PX may be disposed in a stripe structure in which the emission areas are arranged in the first direction DR1, a structure in which the emission areas are disposed in a diamond shape, or a hexagonal structure in which the emission areas having, in plan view, a hexagonal shape are arranged as shown in FIG. 6.

FIG. 7 is a cross-sectional view illustrating an example of a display panel taken along line X1-X1′ of FIG. 5.

Referring to FIG. 7, the display panel 100 may include a semiconductor backplane SBP, a light-emitting element backplane EBP, a display element layer EML, an encapsulation layer TFE, an optical layer OPL, a cover layer CVL, and a polarizing plate POL.

The semiconductor backplane SBP may include the semiconductor substrate SSUB. The semiconductor substrate SSUB may include a plurality of pixel transistors PTR, a plurality of semiconductor insulating films covering the plurality of pixel transistors PTR, and a plurality of contact terminals CTE electrically connected to the plurality of pixel transistors PTR, respectively. The plurality of pixel transistors PTR may be the first to sixth transistors T1 to T6 (see FIG. 3) described with reference to FIG. 3.

The semiconductor substrate SSUB may be a silicon substrate, a germanium substrate, or a silicon-germanium substrate. The semiconductor substrate SSUB may be a substrate doped with a first type impurity. A plurality of well regions WA may be disposed on the top surface of the semiconductor substrate SSUB. The plurality of well regions WA may be regions doped with a second type impurity. The second type impurity may be different from the aforementioned first type impurity. For example, when the first type impurity is a p-type impurity, the second type impurity may be an n-type impurity. Alternatively, when the first type impurity is an n-type impurity, the second type impurity may be a p-type impurity.

Each of the plurality of well regions WA may include a source region SA corresponding to the source electrode of the pixel transistor PTR, a drain region DA corresponding to the drain electrode thereof, and a channel region CH disposed between the source region SA and the drain region DA.

A lower insulating film BINS may be disposed between a gate electrode GE and the well region WA. A side insulating film SINS may be disposed on the side surface of the gate electrode GE. The side insulating film SINS may be disposed on the lower insulating film BINS.

Each of the source region SA and the drain region DA may be a region doped with the first type impurity. The gate electrode GE of the pixel transistor PTR may overlap the well region WA in the third direction DR3. The channel region CH may overlap the gate electrode GE in the third direction DR3. The source region SA may be disposed on a side of the gate electrode GE, and the drain region DA may be disposed on an opposite side of the gate electrode GE.

Each of the plurality of well regions WA may further include a first low-concentration impurity region LDD1 disposed between the channel region CH and the source region SA, and a second low-concentration impurity region LDD2 disposed between the channel region CH and the drain region DA. The first low-concentration impurity region LDD1 may be a region having a lower impurity concentration than the source region SA due to the lower insulating film BINS. The second low-concentration impurity region LDD2 may be a region having a lower impurity concentration than the drain region DA due to the lower insulating film BINS. The distance between the source region SA and the drain region DA may increase due to the presence of the first low-concentration impurity region LDD1 and the second low-concentration impurity region LDD2. Therefore, the length of the channel region CH of each of the pixel transistors PTR increases, so that punch-through and hot carrier phenomena that might be caused by a short channel are inhibited or prevented.

A first semiconductor insulating film SINS1 may be disposed on the semiconductor substrate SSUB. The first semiconductor insulating film SINS1 may be formed of silicon carbonitride (SiCN) or a silicon oxide (SiOx)-based inorganic film, but the present disclosure is not limited thereto.

A second semiconductor insulating film SINS2 may be disposed on the first semiconductor insulating film SINS1. The second semiconductor insulating film SINS2 may be formed of a silicon oxide (SiOx)-based inorganic film, but the present disclosure is not limited thereto.

The plurality of contact terminals CTE may be disposed on the second semiconductor insulating film SINS2. Each of the plurality of contact terminals CTE may be connected to any one of the gate electrode GE, the source region SA, or the drain region DA of each of the pixel transistors PTR through holes penetrating the first semiconductor insulating film SINS1 and the second semiconductor insulating film SINS2. The plurality of contact terminals CTE may be formed of, for example, copper (Cu), aluminum (Al), tungsten (W), molybdenum (Mo), chromium (Cr), gold (Au), titanium (Ti), nickel (Ni), or neodymium (Nd), or an alloy thereof.

A third semiconductor insulating film SINS3 may be disposed on a side surface of each of the plurality of contact terminals CTE. The top surface of each of the plurality of contact terminals CTE may be exposed without being covered by the third semiconductor insulating film SINS3. The third semiconductor insulating film SINS3 may be formed of a silicon oxide (SiOx)-based inorganic film, but the present disclosure is not limited thereto.

The semiconductor substrate SSUB may be replaced with a glass substrate or a polymer resin substrate such as polyimide. In this case, thin film transistors may be disposed on the glass substrate or the polymer resin substrate. The glass substrate may be a rigid substrate that does not bend, and the polymer resin substrate may be a flexible substrate that can be bent or curved.

The light-emitting element backplane EBP may include a plurality of conductive layers ML1 to ML8, a plurality of vias VA1 to VA9, and a plurality of insulating films INS1 to INS9.

The first to eighth conductive layers ML1 to ML8 serve to connect the plurality of contact terminals CTE exposed from the semiconductor backplane SBP to thereby implement the pixel circuit of the first sub-pixel SP1 shown in FIG. 3. For example, the first to sixth transistors T1 to T6 are merely disposed on the semiconductor backplane SBP, and the connection line of the first to sixth transistors T1 to T6 and the first capacitor C1 and the second capacitor C2 may be disposed in the first to eighth conductive layers ML1 to ML8. In addition, a connection portion between the drain region corresponding to the drain electrode of the fourth transistor T4, the source region corresponding to the source electrode of the fifth transistor T5, and the first electrode AND of the light-emitting element LE may also be disposed in the first to eighth conductive layers ML1 to ML8.

The first insulating film INS1 may be disposed on the semiconductor backplane SBP. Each of the first vias VA1 may penetrate the first insulating film INS1 and be connected to the contact terminal CTE exposed from the semiconductor backplane SBP. Each of the first conductive layers ML1 may be disposed on the first insulating film INS1 and may be connected to the first via VA1.

The second insulating film INS2 may be disposed on the first insulating film INS1 and the first conductive layers ML1. Each of the second vias VA2 may penetrate the second insulating film INS2 and be connected to the exposed first conductive layer ML1. Each of the second conductive layers ML2 may be disposed on the second insulating film INS2 and may be connected to the second via VA2.

The third insulating film INS3 may be disposed on the second insulating film INS2 and the second conductive layers ML2. Each of the third vias VA3 may penetrate the third insulating film INS3 and be connected to the exposed second conductive layer ML2. Each of the third conductive layers ML3 may be disposed on the third insulating film INS3 and may be connected to the third via VA3.

A fourth insulating film INS4 may be disposed on the third insulating film INS3 and the third conductive layers ML3. Each of the fourth vias VA4 may penetrate the fourth insulating film INS4 and be connected to the exposed third conductive layer ML3. Each of the fourth conductive layers ML4 may be disposed on the fourth insulating film INS4 and may be connected to the fourth via VA4.

A fifth insulating film INS5 may be disposed on the fourth insulating film INS4 and the fourth conductive layers ML4. Each of the fifth vias VA5 may penetrate the fifth insulating film INS5 and be connected to the exposed fourth conductive layer ML4. Each of the fifth conductive layers ML5 may be disposed on the fifth insulating film INS5 and may be connected to the fifth via VA5.

A sixth insulating film INS6 may be disposed on the fifth insulating film INS5 and the fifth conductive layers ML5. Each of the sixth vias VA6 may penetrate the sixth insulating film INS6 and be connected to the exposed fifth conductive layer ML5. Each of the sixth conductive layers ML6 may be disposed on the sixth insulating film INS6 and may be connected to the sixth via VA6.

A seventh insulating film INS7 may be disposed on the sixth insulating film INS6 and the sixth conductive layers ML6. Each of the seventh vias VA7 may penetrate the seventh insulating film INS7 and be connected to the exposed sixth conductive layer ML6. Each of the seventh conductive layers ML7 may be disposed on the seventh insulating film INS7 and may be connected to the seventh via VA7.

An eighth insulating film INS8 may be disposed on the seventh insulating film INS7 and the seventh conductive layers ML7. Each of the eighth vias VA8 may penetrate the eighth insulating film INS8 and be connected to the exposed seventh conductive layer ML7. Each of the eighth conductive layers ML8 may be disposed on the eighth insulating film INS8 and may be connected to the eighth via VA8.

The first to eighth conductive layers ML1 to ML8 and the first to eighth vias VA1 to VA8 may be formed of substantially the same material. The first to eighth conductive layers ML1 to ML8 and the first to eighth vias VA1 to VA8 may be formed of, for example, copper (Cu), aluminum (Al), tungsten (W), molybdenum (Mo), chromium (Cr), gold (Au), titanium (Ti), nickel (Ni), or neodymium (Nd), or an alloy thereof. First to eighth insulating films INS1 to INS8 may be formed of a silicon oxide (SiOx)-based inorganic film, but the present disclosure is not limited thereto.

The thicknesses of the first conductive layer ML1, the second conductive layer ML2, the third conductive layer ML3, the fourth conductive layer ML4, the fifth conductive layer ML5, and the sixth conductive layer ML6 may be greater than the thicknesses of the first via VA1, the second via VA2, the third via VA3, the fourth via VA4, the fifth via VA5, and the sixth via VA6, respectively. The thickness of each of the second conductive layer ML2, the third conductive layer ML3, the fourth conductive layer ML4, the fifth conductive layer ML5, and the sixth conductive layer ML6 may be greater than the thickness of the first conductive layer ML1. The thickness of the second conductive layer ML2, the thickness of the third conductive layer ML3, the thickness of the fourth conductive layer ML4, the thickness of the fifth conductive layer ML5, and the thickness of the sixth conductive layer ML6 may be substantially the same. For example, the thickness of the first conductive layer ML1 is about 1360 angstroms (Å). The thickness of each of the second conductive layer ML2, the third conductive layer ML3, the fourth conductive layer ML4, the fifth conductive layer ML5, and the sixth conductive layer ML6 is about 1440 Å. The thickness of each of the first via VA1, the second via VA2, the third via VA3, the fourth via VA4, the fifth via VA5, and the sixth via VA6 is about 1150 Å. However, the thicknesses of the first to sixth conductive layers ML1, ML2, ML3, ML4, ML5, and ML6 and the first to sixth vias VA1, VA2, VA3, VA4, VA5, and VA6 are not limited thereto.

The thickness of each of the seventh conductive layer ML7 and the eighth conductive layer ML8 may be greater than the thickness of each of the first conductive layer ML1, the second conductive layer ML2, the third conductive layer ML3, the fourth conductive layer ML4, the fifth conductive layer ML5, and the sixth conductive layer ML6. The thickness of the seventh conductive layer ML7 and the thickness of the eighth conductive layer ML8 may be greater than the thickness of the seventh via VA7 and the thickness of the eighth via VA8, respectively. The thickness of each of the seventh via VA7 and the eighth via VA8 may be greater than the thickness of each of the first via VA1, the second via VA2, the third via VA3, the fourth via VA4, the fifth via VA5, and the sixth via VA6. The thickness of the seventh conductive layer ML7 and the thickness of the eighth conductive layer ML8 may be substantially the same. For example, the thickness of each of the seventh conductive layer ML7 and the eighth conductive layer ML8 is about 9000 Å, and the thickness of each of the seventh via VA7 and the eighth via VA8 is about 6000 Å. However, the thicknesses of the seventh conductive layer ML7, the eighth conductive layer ML8, the seventh via VA7, and the eighth via VA8 are not limited thereto.

A ninth insulating film INS9 may be disposed on the eighth insulating film INS8 and the eighth conductive layer ML8. The ninth insulating film INS9 may be formed of a silicon oxide (SiOx)-based inorganic film, but the present disclosure is not limited thereto.

Each of the ninth vias VA9 may penetrate the ninth insulating film INS9 and be connected to the exposed eighth conductive layer ML8. The ninth vias VA9 may be formed of, for example, copper (Cu), aluminum (Al), tungsten (W), molybdenum (Mo), chromium (Cr), gold (Au), titanium (Ti), nickel (Ni), or neodymium (Nd), or an alloy thereof. The thickness of the ninth via VA9 is about 16500 Å. However, the thickness of the ninth via VA9 is not limited thereto.

The display element layer EML may be disposed on the light-emitting element backplane EBP. The display element layer EML may include light-emitting elements LE each including a reflective electrode layer RL, tenth and eleventh insulating films INS10 and INS11, a tenth via VA10, a first electrode AND, a light-emitting stack IL, and a second electrode CAT; a pixel defining film PDL; and a plurality of trenches TRC.

The reflective electrode layer RL may be disposed on the ninth insulating film INS9. The reflective electrode layer RL may include at least one reflective electrode RL1, RL2, RL3, or RL4. For example, the reflective electrode layer RL may include first to fourth reflective electrodes RL1, RL2, RL3, and RL4 as shown in FIG. 7, but is not limited thereto.

Each of the first reflective electrodes RL1 may be disposed on the ninth insulating film INS9, and may be connected to the ninth via VA9. The first reflective electrodes RL1 may be formed of, for example, copper (Cu), aluminum (Al), tungsten (W), molybdenum (Mo), chromium (Cr), gold (Au), titanium (Ti), nickel (Ni), or neodymium (Nd), or an alloy thereof or compound thereof. For example, the first reflective electrodes RL1 may include titanium nitride (TiN).

Each of the second reflective electrodes RL2 may be disposed on the first reflective electrode RL1. The second reflective electrodes RL2 may be formed of, for example, copper (Cu), aluminum (Al), tungsten (W), molybdenum (Mo), chromium (Cr), gold (Au), titanium (Ti), nickel (Ni), or neodymium (Nd), or an alloy thereof. For example, the second reflective electrodes RL2 may include aluminum (Al).

Each of the third reflective electrodes RL3 may be disposed on the second reflective electrode RL2. The third reflective electrodes RL3 may be formed of, for example, copper (Cu), aluminum (Al), tungsten (W), molybdenum (Mo), chromium (Cr), gold (Au), titanium (Ti), nickel (Ni), or neodymium (Nd), or an alloy thereof or compound thereof. For example, the third reflective electrodes RL3 may include titanium nitride (TiN).

Each of the fourth reflective electrodes RL4 may be disposed on the third reflective electrode RL3. The fourth reflective electrodes RL4 may be formed of, for example, copper (Cu), aluminum (Al), tungsten (W), molybdenum (Mo), chromium (Cr), gold (Au), titanium (Ti), nickel (Ni), or neodymium (Nd), or an alloy thereof. For example, the fourth reflective electrodes RL4 may include titanium (Ti).

Since the second reflective electrode RL2 is an electrode that substantially reflects light from the light-emitting elements LE, the thickness of the second reflective electrode RL2 may be greater than the thickness of each of the first reflective electrode RL1, the third reflective electrode RL3, and the fourth reflective electrode RL4. For example, the thickness of each of the first reflective electrode RL1, the third reflective electrode RL3, and the fourth reflective electrode RL4 is about 100 Å, and the thickness of the second reflective electrode RL2 is about 850 Å. However, the thicknesses of the first to fourth reflective electrodes RL1, RL2, RL3, and RL4 are not limited thereto.

The tenth insulating film INS10 may be disposed on the ninth insulating film INS9. The tenth insulating film INS10 may be disposed between the reflective electrode layers RL adjacent to each other in a horizontal direction. The tenth insulating film INS10 may be formed of a silicon oxide (SiOx)-based inorganic film, but the present disclosure is not limited thereto. In some embodiments, the tenth insulating film INS10 may be disposed between the reflective electrode layers RL and on the reflective electrode layer RL.

The eleventh insulating film INS11 may be disposed on the tenth insulating film INS10 and the reflective electrode layer RL. The eleventh insulating film INS11 may be formed of a silicon oxide (SiOx)-based inorganic film, but the present disclosure is not limited thereto. The tenth insulating film INS10 and the eleventh insulating film INS11 may be an optical auxiliary layer through which light reflected by the reflective electrode layer RL passes, among light emitted from the light-emitting elements LE.

In some embodiments, in at least any one sub-pixel among the first sub-pixel SP1, the second sub-pixel SP2, and the third sub-pixel SP3, in order to adjust the resonance distance of light emitted from the light-emitting elements LE, the total thickness of the insulating film disposed between the first electrode AND and the reflective electrode layer RL may be different in at least two of the first sub-pixel SP1, the second sub-pixel SP2, or the third sub-pixel SP3.

In an embodiment, as shown in the drawing, when the tenth insulating film INS10 is not disposed between the first electrode AND and the reflective electrode layer RL but the eleventh insulating film INS11 is disposed therebetween, the thickness of the eleventh insulating film INS11 disposed in each of the first sub-pixel SP1, the second sub-pixel SP2, and the third sub-pixel SP3 may be different. For example, the thickness of the eleventh insulating film INS11 disposed in the first sub-pixel SP1 may be smaller than the thickness of the eleventh insulating film INS11 disposed in the second sub-pixel SP2, and the thickness of the eleventh insulating film INS11 disposed in the second sub-pixel SP2 may be smaller than the thickness of the eleventh insulating film INS11 disposed in the third sub-pixel SP3.

In another embodiment, in the first sub-pixel SP1, neither the tenth insulating film INS10 nor the eleventh insulating film INS11 may be disposed between the first electrode AND and the reflective electrode layer RL, and in the sub-pixel SP2, any one of the tenth insulating film INS10 or the eleventh insulating film INS11 may be disposed between the first electrode AND and the reflective electrode layer RL, and in the third sub-pixel SP3, both the tenth insulating film INS10 and the eleventh insulating film INS11 may be disposed between the first electrode AND and the reflective electrode layer RL.

In another embodiment, a twelfth insulating film may be further disposed between the first electrode AND and the reflective electrode layer RL. In this case, in the first sub-pixel SP1, any one of the tenth insulating film INS10, the eleventh insulating film INS11, or the twelfth insulating film may be disposed between the first electrode AND and the reflective electrode layer RL, in the second sub-pixel SP2, any two of the tenth insulating film INS10, the eleventh insulating film INS11, and the twelfth insulating film may be disposed between the first electrode AND and the reflective electrode layer RL, and in the third sub-pixel SP3, all the tenth insulating film INS10, the eleventh insulating film INS11, and the twelfth insulating film may be disposed between the first electrode AND and the reflective electrode layer RL.

In an embodiment, the distance between the first electrode AND and the reflective electrode layer RL may be different in the first sub-pixel SP1, the second sub-pixel SP2, and the third sub-pixel SP3. That is, the distance from the reflective electrode layer RL to the second electrode CAT may be adjusted according to the main peak wavelength of the light emitted from each of the first sub-pixel SP1, the second sub-pixel SP2, and the third sub-pixel SP3, the presence/absence or thickness of the tenth insulating film INS10 and the eleventh insulating film INS11 may be set in each of the first sub-pixel SP1, the second sub-pixel SP2, and the third sub-pixel SP3.

Although it is illustrated in the drawing that the total thickness of the insulating film disposed between the first electrode AND and the reflective electrode layer RL increases in the order of the first sub-pixel SP1, the second sub-pixel SP2, and the third sub-pixel SP3, the present disclosure is not limited thereto. That is, it is illustrated that the distance between the first electrode AND and the reflective electrode layer RL in the third sub-pixel SP3 may be greater than the distance between the first electrode AND and the reflective electrode layer RL in the second sub-pixel SP2 and the distance between the first electrode AND and the reflective electrode layer RL in the first sub-pixel SP1, and the distance between the first electrode AND and the reflective electrode layer RL in the second sub-pixel SP2 may be greater than the distance between the first electrode AND and the reflective electrode layer RL in the first sub-pixel SP1, but the present disclosure is not limited thereto. The size relationship of the total thickness of the insulating film disposed between the first electrode AND and the reflective electrode layer RL in each of the first sub-pixel SP1, the second sub-pixel SP2, and the third sub-pixel SP3 may be variously changed depending on the resonance distance.

Each of the tenth vias VA10 may be connected to a reflective electrode layer RL exposed through the tenth insulating film INS10 and/or the eleventh insulating film INS11. The tenth vias VA10 may be formed of, for example, copper (Cu), aluminum (Al), tungsten (W), molybdenum (Mo), chromium (Cr), gold (Au), titanium (Ti), nickel (Ni), or neodymium (Nd), or an alloy thereof. The thickness of the tenth via VA10 in the second sub-pixel SP2 may be less than the thickness of the tenth via VA10 in the third sub-pixel SP3, and the thickness of the tenth via VA10 in the first sub-pixel SP1 may be less than the thickness of the tenth via VA10 in the second sub-pixel SP2, but the present disclosure is not limited thereto.

The first electrode AND of each of the light-emitting elements LE may be disposed on the eleventh insulating film INS11 and connected to the tenth via VA10. The first electrode AND of each of the light-emitting elements LE may be connected to the drain region DA or source region SA of the pixel transistor PTR through the tenth via VA10, the first to fourth reflective electrodes RL1 to RL4, the first to ninth vias VA1 to VA9, the first to eighth conductive layers ML1 to ML8, and the contact terminal CTE. The first electrode AND of each of the light-emitting elements LE may be formed of, for example, copper (Cu), aluminum (Al), tungsten (W), molybdenum (Mo), chromium (Cr), gold (Au), titanium (Ti), nickel (Ni), or neodymium (Nd), or an alloy thereof or compound thereof. For example, the first electrode AND of each of the light-emitting elements LE may be titanium nitride (TiN).

The pixel defining film PDL may be disposed on a portion of the first electrode AND of each of the light-emitting elements LE. The pixel defining film PDL may cover the edge of the first electrode AND of each of the light-emitting elements LE. The pixel defining film PDL may serve to partition the first emission areas EA1, the second emission areas EA2, and the third emission areas EA3.

The first emission area EA1 may be defined as an area in which the first electrode AND, the light-emitting stack IL, and the second electrode CAT are sequentially stacked in the first sub-pixel SP1 to emit light. The second emission area EA2 may be defined as an area in which the first electrode AND, the light-emitting stack IL, and the second electrode CAT are sequentially stacked in the second sub-pixel SP2 to emit light. The third emission area EA3 may be defined as an area in which the first electrode AND, the light-emitting stack IL, and the second electrode CAT are sequentially stacked in the third sub-pixel SP3 to emit light.

The pixel defining film PDL may include first to third pixel defining films PDL1, PDL2, and PDL3. The first pixel defining film PDL1 may be disposed on the edge of the first electrode AND of each of the light-emitting elements LE, the second pixel defining film PDL2 may be disposed on the first pixel defining film PDL1, and the third pixel defining film PDL3 may be disposed on the second pixel defining film PDL2. The first pixel defining film PDL1, the second pixel defining film PDL2, and the third pixel defining film PDL3 may be formed of a silicon oxide (SiOx)-based inorganic film, but the present disclosure is not limited thereto. The first pixel defining film PDL1, the second pixel defining film PDL2, and the third pixel defining film PDL3 may each have a thickness of about 500 Å.

When the first pixel defining film PDL1, the second pixel defining film PDL2, and the third pixel defining film PDL3 may be formed as one pixel defining film, the height of the pixel defining film increases, and a first encapsulation inorganic film TFE1 may be cut off due to step coverage. Step coverage refers to the ratio of the degree of thin film coated on an inclined portion to the degree of thin film coated on a flat portion. The lower the step coverage, the more likely it is that the thin film will be cut off at inclined portions.

Therefore, in order to reduce or prevent the likelihood of the first encapsulation inorganic film TFE1 being cut off due to the step coverage, the first pixel defining film PDL1, the second pixel defining film PDL2, and the third pixel defining film PDL3 may have a cross-sectional structure having a stepped portion. For example, the width of the first pixel defining film PDL1 may be greater than the width of the second pixel defining film PDL2 and the width of the third pixel defining film PDL3, and the width of the second pixel defining film PDL2 may be greater than the width of the third pixel defining film PDL3. Each of the width of the first pixel defining film PDL1, the width of the second pixel defining film PDL2, and the width of the third pixel defining film PDL3 refers to the length in the horizontal direction perpendicular to the third direction DR3.

Each of the plurality of trenches TRC may penetrate the first pixel defining film PDL1, the second pixel defining film PDL2, and the third pixel defining film PDL3. Furthermore, each of the plurality of trenches TRC may penetrate the eleventh insulating film INS11. The eleventh insulating film INS11 may be partially recessed at each of the plurality of trenches TRC.

At least one trench TRC may be disposed between the neighboring sub-pixels SP1, SP2, and SP3. Although FIG. 7 illustrates that two trenches TRC may be disposed between the neighboring sub-pixels SP1, SP2, and SP3, the present disclosure is not limited thereto.

The light-emitting stack IL may include a plurality of intermediate layers. FIG. 7 illustrates that the light-emitting stack IL has a three-tandem structure including a first stack layer IL1, a second stack layer IL2, and a third stack layer IL3, but the present disclosure is not limited thereto. For example, the light-emitting stack IL may have a two-tandem structure including two intermediate layers.

In the three-tandem structure, the light-emitting stack IL may have a tandem structure including a plurality of stack layers IL1, IL2, and IL3 that emit different lights. For example, the light-emitting stack IL may include the first stack layer IL1 that emits light of the first color, the second stack layer IL2 that emits light of the third color, and the third stack layer IL3 that emits light of the second color. The first stack layer IL1, the second stack layer IL2, and the third stack layer IL3 may be sequentially stacked.

The first stack layer IL1 may have a structure in which a first hole transport layer, a first organic light-emitting layer that emits light of the first color, and a first electron transport layer are sequentially stacked. The second stack layer IL2 may have a structure in which a second hole transport layer, a second organic light-emitting layer that emits light of the third color, and a second electron transport layer are sequentially stacked. The third stack layer IL3 may have a structure in which a third hole transport layer, a third organic light-emitting layer that emits light of the second color, and a third electron transport layer are sequentially stacked.

A first charge generation layer for supplying holes to the second stack layer IL2 and supplying electrons to the first stack layer IL1 may be disposed between the first stack layer IL1 and the second stack layer IL2. The first charge generation layer may include an N-type charge generation layer that supplies electrons to the first stack layer IL1 and a P-type charge generation layer that supplies holes to the second stack layer IL2. The N-type charge generation layer may include a dopant of a metal material.

A second charge generation layer for supplying holes to the third stack layer IL3 and supplying electrons to the second stack layer IL2 may be disposed between the second stack layer IL2 and the third stack layer IL3. The second charge generation layer may include an N-type charge generation layer that supplies electrons to the second stack layer IL2 and a P-type charge generation layer that supplies holes to the third stack layer IL3.

The first stack layer IL1 may be disposed on the first electrodes AND and the pixel defining film PDL, and may be disposed on the bottom surface of each trench TRC. Due to the trench TRC, the first stack layer IL1 may be cut off between the neighboring sub-pixels SP1, SP2, and SP3. The second stack layer IL2 may be disposed on the first stack layer IL1. Due to the trench TRC, the second stack layer IL2 may be cut off between the neighboring sub-pixels SP1, SP2, and SP3. A cavity ESS or an empty space may be disposed between the first stack layer IL1 and the second stack layer IL2. The third stack layer IL3 may be disposed on the second stack layer IL2. The third stack layer IL3 is not cut off by the trench TRC and may be disposed to cover the second stack layer IL2 in each of the trenches TRC. That is, in the three-tandem structure, each of the plurality of trenches TRC may be a structure for cutting off the first and second stack layers IL1 and IL2, the first charge generation layer, and the second charge generation layer of the display element layer EML between the sub-pixels SP1, SP2, and SP3 adjacent to each other. In addition, in the two-tandem structure, each of the trenches TRC may be a structure for cutting off the charge generation layer disposed between a lower intermediate layer and an upper intermediate layer, and the lower intermediate layer.

In order to stably cut off the first and second stack layers IL1 and IL2 of the display element layer EML between adjacent sub-pixels SP1, SP2, and SP3, the height of each of the plurality of trenches TRC may be greater than the height of the pixel defining film PDL. The height of each of the plurality of trenches TRC may refer to the length of each of the plurality of trenches TRC in the third direction DR3. The height of the pixel defining film PDL may refer to the length of the pixel defining film PDL in the third direction DR3. In order to cut off the first to third stack layers IL1, IL2, and IL3 of the display element layer EML between the neighboring sub-pixels SP1, SP2, and SP3, another structure may exist instead of the trench TRC. For example, instead of the trench TRC, a reverse tapered partition wall may be disposed on the pixel defining film PDL.

The number of the stack layers IL1, IL2, and IL3 that emit different lights is not limited to that shown in FIG. 7. For example, the light-emitting stack IL may include two intermediate layers. In this case, one of the two intermediate layers may be substantially the same as the first stack layer IL1, and the other one of the two intermediate layers may include a second hole transport layer, a second organic light-emitting layer, a third organic light-emitting layer, and a second electron transport layer. In this case, a charge generation layer for supplying electrons to an intermediate layer and supplying holes to the other intermediate layer may be disposed between the two intermediate layers.

In addition, FIG. 7 illustrates that the first to third stack layers IL1, IL2, and IL3 may be all disposed in the first emission area EA1, the second emission area EA2, and the third emission area EA3, but the present disclosure is not limited thereto. For example, the first stack layer IL1 may be disposed in the first emission area EA1, and may be omitted from the second emission area EA2 and the third emission area EA3. Furthermore, the second stack layer IL2 may be disposed in the second emission area EA2 and may be omitted from the first emission area EA1 and the third emission area EA3. Further, the third stack layer IL3 may be disposed in the third emission area EA3 and may be omitted from the first emission area EA1 and the second emission area EA2. In this case, first to third color filters CF1, CF2, and CF3 of the optical layer OPL may be omitted.

The second electrode CAT may be disposed on the third stack layer IL3. The second electrode CAT may be disposed on the third stack layer IL3 in each of the plurality of trenches TRC. The second electrode CAT may be formed of a transparent conductive material (TCO) such as ITO or IZO that can transmit light or a semi-transmissive conductive material such as magnesium (Mg), silver (Ag), or an alloy of Mg and Ag. When the second electrode CAT is formed of a semi-transmissive conductive material, the light emission efficiency may be improved in each of the first to third sub-pixels SP1, SP2, and SP3 due to a micro-cavity effect.

The encapsulation layer TFE may be disposed on the display element layer EML. The encapsulation layer TFE may include at least one inorganic film TFE1 and TFE2 to reduce or prevent oxygen or moisture from permeating into the display element layer EML. For example, the encapsulation layer TFE may include a first encapsulation inorganic film TFE1, and a second encapsulation inorganic film TFE2.

The first encapsulation inorganic film TFE1 may be disposed on the second electrode CAT. The first encapsulation inorganic film TFE1 may be formed as a multilayer in which one or more inorganic films selected from silicon nitride (SiNx), silicon oxy nitride (SiON), or silicon oxide (SiOx) may be alternately stacked. The first encapsulation inorganic film TFE1 may be formed by a chemical vapor deposition (CVD) process.

The second encapsulation inorganic film TFE2 may be disposed on the first encapsulation inorganic film TFE1. The second encapsulation inorganic film TFE2 may be formed of titanium oxide (TiOx) or aluminum oxide (AlOx), but the present disclosure is not limited thereto. The second encapsulation inorganic film TFE2 may be formed by an atomic layer deposition (ALD) process. The thickness of the second encapsulation inorganic film TFE2 may be less than the thickness of the first encapsulation inorganic film TFE1.

The display panel 100 may further include an organic film APL. An organic film APL may be a layer for increasing the interfacial adhesion between the encapsulation layer TFE and the optical layer OPL. The organic film APL may be an organic film such as acrylic resin, epoxy resin, phenolic resin, polyamide resin, or polyimide resin.

The optical layer OPL may include a plurality of color filters CF1, CF2, and CF3, a plurality of lenses LNS, and a filling layer FIL. The plurality of color filters CF1, CF2, and CF3 may include the first to third color filters CF1, CF2, and CF3. The first to third color filters CF1, CF2, and CF3 may be disposed on the organic film APL.

The first color filter CF1 may overlap the first emission area EA1 of the first sub-pixel SP1. The first color filter CF1 may transmit light of the first color, i.e., light of a red wavelength band. The red wavelength band may be about 600 nm to about 750 nm. Thus, the first color filter CF1 may transmit light of the first color among light emitted from the first emission area EA1.

The second color filter CF2 may overlap the second emission area EA2 of the second sub-pixel SP2. The second color filter CF2 may transmit light of the second color, i.e., light of a green wavelength band. The green wavelength band may be about 480 nm to about 560 nm. Thus, the second color filter CF2 may transmit light of the second color among light emitted from the second emission area EA2.

The third color filter CF3 may overlap the third emission area EA3 of the third sub-pixel SP3. The third color filter CF3 may transmit light of the third color, i.e., light of a blue wavelength band. The blue wavelength band may be about 370 nm to about 460 nm. Thus, the third color filter CF3 may transmit light of the third color among light emitted from the third emission area EA3.

The plurality of lenses LNS may be disposed on the first color filter CF1, the second color filter CF2, and the third color filter CF3, respectively. Each of the plurality of lenses LNS may be a structure for increasing the proportion of light directed to the front of the display device 10. Each of the plurality of lenses LNS may have a cross-sectional shape that is convex in an upward direction. In some embodiments, the plurality of lenses LNS may be a micro lens array (MLA).

The filling layer FIL may be disposed on the plurality of lenses LNS. The filling layer FIL may have a predetermined refractive index, and light travels in the third direction DR3 at an interface between the filling layer FIL and the plurality of lenses LNS. Further, the filling layer FIL may be a planarization layer. The filling layer FIL may be an organic film such as acrylic resin, epoxy resin, phenolic resin, polyamide resin, or polyimide resin.

The cover layer CVL may be disposed on the filling layer FIL. The cover layer CVL may be a glass substrate or a polymer resin. When the cover layer CVL is a glass substrate, it may be attached onto the filling layer FIL. In this case, the filling layer FIL serves to bond the cover layer CVL. When the cover layer CVL is a glass substrate, it may serve as an encapsulation substrate. When the cover layer CVL is a polymer resin, it may be directly applied onto the filling layer FIL.

The polarizing plate POL may be disposed on a surface of the cover layer CVL. The polarizing plate POL may be a structure for reducing or preventing a degradation in visibility caused by reflection of external light. The polarizing plate POL may include a linear polarizing plate and a phase retardation film. For example, the phase retardation film may be a λ/4 plate (quarter-wave plate), but the present disclosure is not limited thereto. The polarizing plate POL may be omitted. For example, the polarizing plate POL may be omitted when visibility degradation caused by reflection of external light is sufficiently inhibited by the first to third color filters CF1, CF2, and CF3.

The drawing illustrates that the polarizing plate POL is mounted on the display panel 100, but the present disclosure is not limited thereto. For example, the polarizing plate POL may be included in the optical module 800 (see FIG. 9), and in this case, the polarizing plate POL may have the same component as a first optical module 810 (see FIG. 9) of the optical module 800 (see FIG. 9). That is, the polarizing plate POL may be provided by being mounted on the display panel 100 or may be provided by being mounted on the optical module 800 (see FIG. 9).

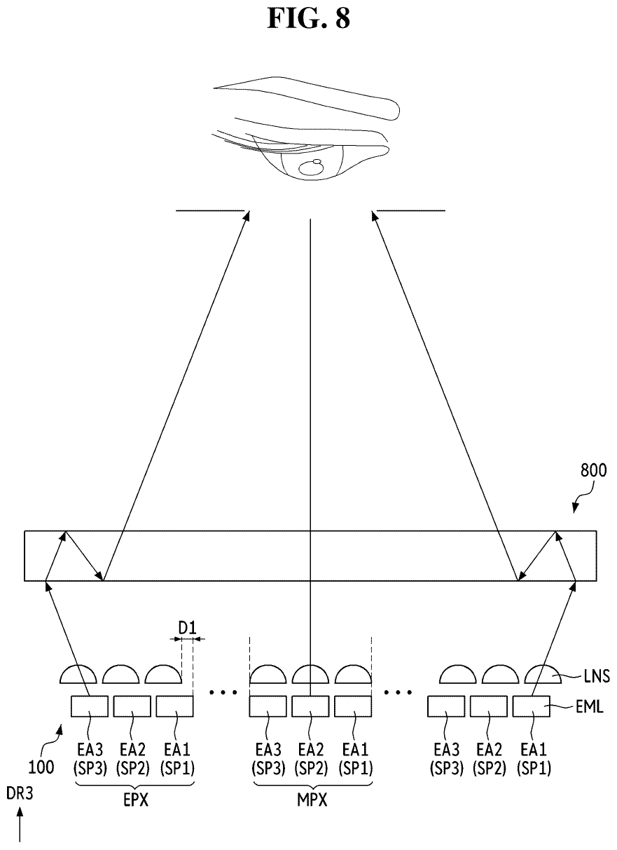

FIG. 8 is a schematic cross-sectional view illustrating a display element layer, lenses, and an optical module of a display device according to an embodiment.

Referring to FIG. 8 in addition to FIG. 2 and FIG. 7, some of the plurality of lenses LNS may be disposed in a straight line with each of the emission areas EA1, EA2, and EA3, and some others of the plurality of lenses LNS may be disposed to be shifted in one direction with respect to each of the emission areas EA1, EA2, and EA3.

For example, the display device 10 may include a middle pixel MPX and an edge pixel EPX. The middle pixel MPX refers to the pixel PX positioned in the middle among the pixels PX, and the edge pixel EPX refers to the pixel PX positioned at the edge among the pixels PX.

The plurality of sub-pixels SP1, SP2, and SP3 included in the middle pixel MPX may be disposed in parallel with the plurality of lenses LNS disposed thereabove, respectively. For example, the plurality of sub-pixels SP1, SP2, and SP3 included in the middle pixel MPX may be respectively disposed in a straight line in the thickness direction (e.g., the third direction DR3) of the display panel 100 with respect to the plurality of lenses LNS disposed thereabove.

The plurality of sub-pixels SP1, SP2, and SP3 included in the edge pixel EPX may be respectively disposed to be shifted by a first distance D1 with respect to the plurality of lenses LNS disposed thereabove. For example, the plurality of sub-pixels SP1, SP2, and SP3 included in the edge pixel EPX may be respectively disposed to be offset horizontally in the thickness direction (e.g., the third direction DR3) of the display panel 100 with respect to the plurality of lenses LNS disposed thereabove. Lenses LNS disposed at opposite end portions of the optical module 800 with respect to the middle pixel MPX may be shifted in opposite directions.

For the edge pixel EPX, when the plurality of lenses LNS is offset from the emission areas EA1, EA2, and EA3, the lenses LNS may alter the direction of the light due to the principles of refraction. For example, when an emission area is not aligned with the optical axis of a corresponding lens, the lens may introduce asymmetry in the path of the light rays. Further, larger offsets may cause larger angular shifts.

In the display device 10 according to an embodiment, the size of the first distance D1 that is the degree to which the plurality of sub-pixels SP1, SP2, and SP3 are shifted with respect to the plurality of lenses LNS may increase in the direction from the middle pixel MPX to the edge pixel EPX. Accordingly, the average luminance amount of the display device 10 according to an embodiment may be improved according to the chief ray array (CRA) angle distribution. That is, the overall luminous efficiency of the display device 10 may be improved from various angles.

Specifically, when light emitted from the plurality of sub-pixels SP1, SP2, and SP3 included in the middle pixel MPX is incident on the optical module 800, the light may be incident generally parallel to a normal line (e.g., the vertical line in the drawing). On the other hand, when light emitted from the plurality of sub-pixels SP1, SP2, and SP3 included in the edge pixel EPX is incident on the optical module 800, the light may be incident generally at an angle with respect to the normal line. Accordingly, the shift may be by the first distance D1, and the lens LNS (e.g., approximately the middle of the lens LNS) may be disposed on an extension line extending from the display element layer EML of each of the pixels PX to the incident point of the optical module 800, and the average luminance amount according to the chief ray array (CRA) angle distribution may be improved. Further, an amount of the shift may increase away from the middle pixel MPX. For example, the shift at pixels between the middle pixel MPX and the edge pixel EPX may be gradually increased until the shift is equal to the first distance D1 at the edge pixel EPX.

According to an embodiment, the plurality of lenses LNS may be provided with different shapes. For example, a lens having a shorter focal length may cause an increase in the angular deflection for a same offset. Accordingly, the plurality of lenses LNS of the display panel 100 may be provided having different shapes to adjust, for example, the field of view (FOV). Further, a combination of the plurality of lenses LNS having different offsets and different shapes may be implemented.

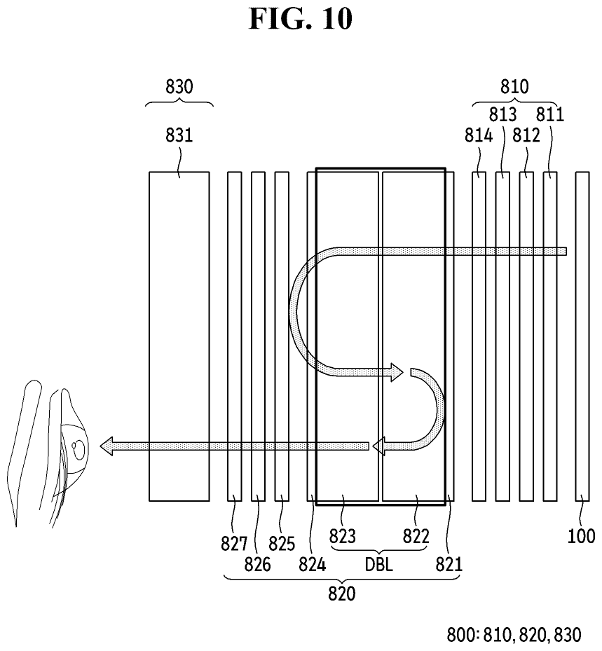

FIG. 9 and FIG. 10 are cross-sectional views showing a display device according to an embodiment.

Referring to FIG. 9 and FIG. 10 in addition to FIG. 7 and FIG. 8, the display device 10 may include the display panel 100 and the optical module 800 disposed on the display panel 100.

Since the display panel 100 has been described with reference to FIG. 7 and the like, a repeated description of the display panel 100 may be omitted.

The optical module 800 may include the first optical module 810, a second optical module 820, and a third optical module 830. The first optical module 810 may be disposed on the display panel 100, the second optical module 820 may be disposed on the first optical module 810, and the third optical module 830 may be disposed on the second optical module 820.

In some embodiments, the first optical module 810 may be disposed directly on the display panel 100. For example, the first optical module 810 may be directly attached to the display panel 100. The second optical module 820 may be disposed to be spaced apart from the first optical module 810 by a second distance D2. The third optical module 830 may be disposed to be spaced apart from the second optical module 820 by a third distance D3. Gaps may be disposed between the second optical module 820 and the first optical module 810 and between the third optical module 830 and the second optical module 820, respectively. The gaps may be air gaps filled with air, which may be positioned between the second optical module 820 and the first optical module 810 and between the third optical module 830 and the second optical module 820, respectively. The air gaps may separate a refractive effect of the first optical module 810, the second optical module 820, and the third optical module 830, allowing each optical module to independently bend light. Further, various parameters of the display device 10 may be adjusted according to the spacing between the optical modules. For example, an effective focal length of a display device 10 may be adjusted according to the spacing between the optical modules. Other parameters may be adjusted, such as reducing aberrations and controlling an amount of light divergence or light convergence.

The first optical module 810 may include a first phase retardation film 811, a first polarizing film 812, a second phase retardation film 813, and a first coating film 814. The second optical module 820 may include a semi-transmissive reflective film 821, a first lens DBL, a third phase retardation film 824, a second polarizing film 825, a third polarizing film 826, and a second coating film 827. The third optical module 830 may include a second lens 831. The first lens DBL of the second optical module 820 may include a first sub-lens 822 and a second sub-lens 823.

The first optical module 810 may be the same component as the polarizing plate POL of the display panel 100 described with reference to FIG. 7. For example, the display device 10 may include the polarizing plate POL of the display panel 100 or the first optical module 810 of the optical module 800.

The first phase retardation film 811 may be disposed on the display panel 100. For example, the first phase retardation film 811 may be disposed on the cover layer CVL of the display panel 100. The first phase retardation film 811 may delay the phase of light that has passed through the first phase retardation film 811. When linearly polarized light passes through the first phase retardation film 811, the light may be circularly polarized or elliptically polarized, and when circularly polarized or elliptically polarized light passes through the first phase retardation film 811, the light may be linearly polarized. In an embodiment, the first phase retardation film 811 may be a λ/4 plate (quarter-wave plate). In some embodiments, the first phase retardation film 811 may be omitted.

The first polarizing film 812 may be disposed on the first phase retardation film 811. The first polarizing film 812 may have a first polarization axis extending in one direction. The first polarizing film 812 may be a linear polarizing film. The first polarizing film 812 may linearly polarize light in the direction of the first polarization axis. For example, the first polarizing film 812 may pass light vibrating in a direction parallel to the first polarization axis and may block light vibrating in other directions.

In an embodiment, the first polarizing film 812 may be an absorption-type polarizing film. In this case, the first polarizing film 812 may pass light vibrating in a direction parallel to the first polarization axis and may absorb light vibrating in other directions.

The second phase retardation film 813 may be disposed on the first polarizing film 812. The second phase retardation film 813 may delay the phase of light that has passed through the second phase retardation film 813. When linearly polarized light passes through the second phase retardation film 813, the light may be circularly polarized or elliptically polarized, and when circularly polarized or elliptically polarized light passes through the second phase retardation film 813, the light may be linearly polarized. In an embodiment, the second phase retardation film 813 may be a λ/4 plate (quarter-wave plate).

The first coating film 814 may be disposed on the second phase retardation film 813. The first coating film 814 may be an anti-reflection film. The first coating film 814 may be formed by anti-reflection coating. The first coating film 814 may inhibit or prevent light passing through the top surface (left side in the drawing) of the first optical module 810 from being reflected. Accordingly, the light output efficiency may be improved, and the occurrence of stray light may be reduced.

The first lens DBL may be disposed on the first optical module 810. For example, the first lens DBL may be disposed on the first coating film 814 of the first optical module 810. The first lens DBL may be disposed to be spaced apart from the first optical module 810. The first lens DBL may magnify an image formed by light emitted from the display panel 100.

The first lens DBL may be a doublet lens. For example, the first lens DBL may be a lens in which the first sub-lens 822 and the second sub-lens 823 are bonded. An adhesive layer may be disposed between the first sub-lens 822 and the second sub-lens 823. For example, entire surfaces of the first sub-lens 822 and the second sub-lens 823 may be bonded together. However, the present disclosure is not limited thereto. For example, the first lens DBL may include an air gap or an oil gap disposed between the first sub-lens 822 and the second sub-lens 823. An oil spaced doublet lens may be sealed at an edge portion. In some embodiments, an oil spaced doublet lens may have improved cooling properties.

In some embodiments, the first lens DBL may include plastic. For example, the first lens DBL may include at least one of polymethylmethacrylate (PMMA)-based plastic, cyclic olefin copolymer (COC)-based plastic, or polycarbonate (PC)-based plastic. The first sub-lens 822 and the second sub-lens 823 may include different materials. For example, the first sub-lens 822 may include at least one of polymethylmethacrylate (PMMA)-based plastic or cyclic olefin copolymer (COC)-based plastic, and the second sub-lens 823 may include polycarbonate (PC)-based plastic.

The display device 10 according to an embodiment may reduce the thickness of the optical module 800 by including a doublet lens. Accordingly, a range of distances that the display device 10 may be adjusted to from a user's eyes may be increased, and eye comfort may be ensured. Additionally, the field of view (FOV) may be increased through aberration correction and focus correction by using a doublet lens. Additionally, since the first lens DBL includes plastic, processing of the doublet lens and aspherical surface processing may be facilitated.

Herein, the average curvature of a lens is described. The average curvature of a lens may be understood as a measure of how much the surfaces of the lens are curved, for example, determined based on the radii of curvature of a front lens surface and a back lens surface that is disposed opposite the front lens surface.

In some embodiments, the average curvatures of a first surface DBLa and a second surface DBLb of the first lens DBL may be different. For example, the average curvature of the first surface DBLa of the first lens DBL may be greater than the average curvature of the second surface DBLb. In an embodiment, the first surface DBLa of the first lens DBL may be an aspherical surface including a plurality of curvatures, and the second surface DBLb may be a flat surface, but the present disclosure is not limited thereto. The first surface DBLa of the first lens DBL is a surface facing the first optical module 810, and the second surface DBLb is a surface facing the third optical module 830.

In the display device 10 according to an embodiment, the first lens DBL may include an aspherical surface, and the color crosstalk (or color X-talk) phenomenon may be improved. In addition, as described above with reference to FIG. 8, by adjusting the first distance D1 that is the degree to which the plurality of sub-pixels SP1, SP2, and SP3 are shifted with respect to the plurality of lenses LNS in the direction from the middle pixel MPX to the edge pixel EPX and simultaneously adjusting each of the plurality of curvatures of the aspherical surface of the first lens DBL, the average luminance amount according to the chief ray array (CRA) angle distribution may be further improved.

The semi-transmissive reflective film 821 may be disposed on the first surface DBLa of the first lens DBL. The semi-transmissive reflective film 821 may be disposed between the first lens DBL and the first optical module 810. The semi-transmissive reflective film 821 may transmit a portion of light and reflect a remaining portion. For example, the semi-transmissive reflective film 821 may be a half mirror.

Light transmitted through the semi-transmissive reflective film 821 may be transmitted without phase change. Light reflected from the semi-transmissive reflective film 821 may be reflected with the phase thereof reversed. For example, left-circularly polarized light may be reflected from the semi-transmissive reflective film 821 to be right-circularly polarized light, and the right-circularly polarized light may be reflected from the semi-transmissive reflective film 821 to be left-circularly polarized light.

The semi-transmissive reflective film 821 may be conformally formed according to the shape of the first surface DBLa of the first lens DBL. Since the first surface DBLa of the first lens DBL is an aspherical surface including a plurality of curvatures, the viewing angle and the magnification ratio may be increased. Accordingly, the number of components of the optical module 800 may be reduced and the thickness of the display device 10 may be reduced.

The third phase retardation film 824 may be disposed on the second surface DBLb of the first lens DBL. The third phase retardation film 824 may delay the phase of light that has passed through the third phase retardation film 824. When linearly polarized light passes through the third phase retardation film 824, the light may be circularly polarized or elliptically polarized, and when circularly polarized or elliptically polarized light passes through the third phase retardation film 824, the light may be linearly polarized. In an embodiment, the third phase retardation film 824 may be a λ/4 plate (quarter-wave plate).

The second polarizing film 825 may be disposed on the third phase retardation film 824. The second polarizing film 825 may have a second polarization axis extending in one direction. The second polarizing film 825 may be a linear polarizing film. The second polarizing film 825 may linearly polarize light in the direction of the second polarization axis. For example, the second polarizing film 825 may pass light vibrating in a direction parallel to the second polarization axis and may block light vibrating in other directions.

In an embodiment, the second polarizing film 825 may be a transflective polarizing film. In this case, the second polarizing film 825 may pass light vibrating in a direction parallel to the second polarization axis and may reflect light vibrating in other directions.

The third polarizing film 826 may be disposed on the second polarizing film 825. The third polarizing film 826 may have a third polarization axis extending in one direction. The third polarizing film 826 may be a linear polarizing film. The third polarizing film 826 may linearly polarize light in the direction of the third polarization axis. For example, the third polarizing film 826 may pass light vibrating in a direction parallel to the third polarization axis and may block light vibrating in other directions. In some embodiments, the third polarizing film 826 may be omitted.

In an embodiment, the third polarizing film 826 may be an absorption-type polarizing film. In this case, the third polarizing film 826 may pass light vibrating in a direction parallel to the third polarization axis and may absorb light vibrating in other directions.

The second coating film 827 may be disposed on the third polarizing film 826. The second coating film 827 may be an anti-reflection film. The second coating film 827 may be formed by anti-reflection coating. The second coating film 827 may inhibit or prevent light passing through the top surface (left side in the drawing) of the second optical module 820 from being reflected. Accordingly, the light output efficiency may be improved, and the occurrence of stray light may be reduced.

The second lens 831 may be disposed on the second optical module 820. For example, the second lens 831 may be disposed on the second coating film 827 of the second optical module 820. The second lens 831 may be disposed to be spaced apart from the second optical module 820. The second lens 831 may magnify an image formed by light emitted from the display panel 100.

The second lens 831 may be a single lens. Lenses of various shapes, such as a convex lens, a meniscus lens, and a Fresnel lens, may be used as the second lens 831, and the shape of the second lens 831 is not limited.

In some embodiments, the second lens 831 may include plastic. For example, the second lens 831 may include at least one of polymethylmethacrylate (PMMA)-based plastic or cyclic olefin copolymer (COC)-based plastic.

In some embodiments, the average curvatures of a first surface 831a and a second surface 831b of the second lens 831 may be different. For example, the average curvature of the first surface 831a of the second lens 831 may be less than the average curvature of the second surface 831b. In an embodiment, the first surface 831a and the second surface 831b of the second lens 831 may be aspherical surfaces including a plurality of curvatures. The first surface 831a of the second lens 831 is a surface facing the second optical module 820, and the second surface 831b is a surface positioned on the opposite side of the first surface 831a.

In the display device 10 according to an embodiment, the second lens 831 may include an aspherical surface, and the color crosstalk (or color X-talk) phenomenon may be improved. In addition, as described above with reference to FIG. 8, by adjusting the first distance D1 that is the degree to which the plurality of sub-pixels SP1, SP2, and SP3 are shifted with respect to the plurality of lenses LNS in the direction from the middle pixel MPX to the edge pixel EPX and simultaneously adjusting each of the plurality of curvatures of the aspherical surface of the second lens 831, the average luminance amount according to the chief ray array (CRA) angle distribution may be further improved.

In some embodiments, a third coating film may be further disposed on the second surface 831b of the second lens 831. The third coating film may be an anti-reflection film. The third coating film may be formed by anti-reflection coating. The third coating film may inhibit or prevent light passing through the top surface (left side in the drawing) of the third optical module 830 from being reflected. Accordingly, the light output efficiency may be improved, and the occurrence of stray light may be reduced.

In some embodiments, at least one of the first coating film 814, the second coating film 827, or the third coating film may be omitted depending on the degree of improvement in transmittance and reflectivity of each member.

The first polarization axis of the first polarizing film 812 and the second polarization axis of the second polarizing film 825 may be perpendicular to each other. For example, when the first polarization axis extends in the third direction DR3 that is a perpendicular direction, the second polarization axis may extend in a horizontal direction perpendicular to the third direction DR3.

The second phase retardation film 813 may have a first optical axis. The first optical axis of the second phase retardation film 813 may be tilted by an angle in the range of greater than 0 degrees and less than 90 degrees relative to the first polarization axis of the first polarizing film 812 and/or the second polarization axis of the second polarizing film 825. In an embodiment, the first optical axis may be tilted by an angle of about 45 degrees relative to the first polarization axis and/or the second polarization axis, but the present disclosure is not limited thereto.

The third phase retardation film 824 may have a second optical axis. The second optical axis of the third phase retardation film 824 may be tilted by an angle in the range of greater than 0 degrees and less than 90 degrees relative to the first polarization axis of the first polarizing film 812 and/or the second polarization axis of the second polarizing film 825. In an embodiment, the second optical axis may be tilted by an angle of about 45 degrees relative to the first polarization axis and/or the second polarization axis, but the present disclosure is not limited thereto.

The direction in which the first optical axis of the second phase retardation film 813 is tilted with respect to the first polarization axis and/or the second polarization axis may be opposite to the direction in which the second optical axis of the third phase retardation film 824 is tilted with respect to the first polarization axis and/or the second polarization axis. For example, the first optical axis of the second phase retardation film 813 may be tilted in the −45 degree direction with respect to the first polarization axis and/or the second polarization axis, and the second optical axis of the third phase retardation film 824 may be tilted in the +45 degree direction with respect to the first polarization axis and/or the second polarization axis. Alternatively, the first optical axis of the second phase retardation film 813 may be tilted in the +45 degree direction with respect to the first polarization axis and/or the second polarization axis, and the second optical axis of the third phase retardation film 824 may be tilted in the −45 degree direction with respect to the first polarization axis and/or the second polarization axis.

The phase retardation direction of light that has passed through the second phase retardation film 813 may be different from the phase retardation direction of light that has passed through the third phase retardation film 824. For example, light that has passed through the second phase retardation film 813 may be delayed by about −λ/4, and light that has passed through the third phase retardation film 824 may be delayed by about +λ/4.

The display device 10 according to an embodiment may implement folded optics system that folds the optical path by including the optical module 800. Accordingly, the total track length, which is the total length of the optical path, may be increased while simultaneously reducing the thickness of the display device 10.

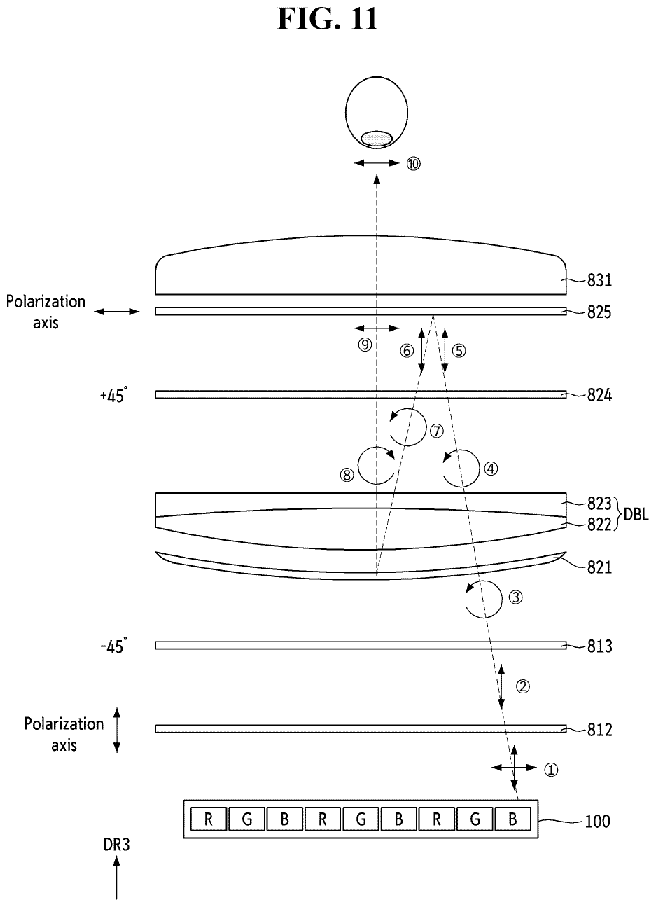

Hereinafter, the path and polarization state of light moving through the folded optics system of the display device 10, described herein with reference to FIG. 11.

FIG. 11 is a schematic diagram illustrating a path and polarization state of light emitted from a display device according to an embodiment. FIG. 11 does not illustrate the first phase retardation film 811 and the third polarizing film 826. Although the first phase retardation film 811 and the third polarizing film 826 may be included, the path and polarization state of light emitted from the display device 10 may be the same as those described with reference to FIG. 11.

Referring to FIG. 11 in addition to FIG. 9 and FIG. 10, it is illustrated that the first polarization axis of the first polarizing film 812 extends in the perpendicular direction and the second polarization axis of the second polarizing film 825 extends in the horizontal direction. In addition, it is illustrated that the first polarizing film 812 is an absorption-type polarizing film and the second polarizing film 825 is a reflective polarizing film. In addition, it is illustrated that the first optical axis of the second phase retardation film 813 is tilted by about −45 degrees with respect to the perpendicular direction and the second optical axis of the third phase retardation film 824 is tilted by about +45 degrees with respect to the perpendicular direction.

Light emitted from the display panel 100 may be unpolarized light \textcircled{1}.

A portion of the unpolarized light \textcircled{1} with the first polarization axis in the perpendicular direction may pass through the first polarizing film 812 and be converted into vertical linear polarized light \textcircled{2} that vibrates in the perpendicular direction.

The vertical linear polarized light \textcircled{2} that has passed through the first polarizing film 812 may pass through the second phase retardation film 813 with the first optical axis tilted by about-45 degrees with respect to the perpendicular direction and be converted into left-circularly polarized light \textcircled{3}.

Part of the left-circularly polarized light \textcircled{3} that has passed through the second phase retardation film 813 may pass through the semi-transmissive reflective film 821. The left-circularly polarized light \textcircled{3} that has passed through the semi-transmissive reflective film 821 may have the same polarization state as the left-circularly polarized light \textcircled{3} that has passed through the second phase retardation film 813 without a change in the polarization state. In some embodiments, the remaining portion of the left-circularly polarized light \textcircled{3} that has passed through the second phase retardation film 813 may be reflected by the semi-transmissive reflective film 821.

The left-circularly polarized light \textcircled{3} that has passed through the semi-transmissive reflective film 821 may pass through the first lens DBL, and the image thereof may be magnified. Left-circularly polarized light \textcircled{4} that has passed through the first lens DBL may have the same polarization state as the left-circularly polarized light \textcircled{3} that has passed through the semi-transmissive reflective film 821 without a change in the polarization state.

The left-circularly polarized light \textcircled{4} that has passed through the first lens DBL may pass through the third phase retardation film 824 with the second optical axis tilted by about +45 degrees with respect to the perpendicular direction and be converted back into vertical linear polarized light \textcircled{5}.

Since the vertical linear polarized light \textcircled{5} that has passed through the third phase retardation film 824 may include light polarized in a direction different from the second polarization axis in the horizontal direction, this light may be reflected by the second polarizing film 825. Vertical linear polarized light \textcircled{6} reflected from the second polarizing film 825 may have the same polarization state as the vertical linear polarized light \textcircled{5} that has passed through the third phase retardation film 824 without a change in the polarization state.

The vertical linear polarized light \textcircled{6} reflected from the second polarizing film 825 may pass through the third phase retardation film 824 with the second optical axis tilted by about +45 degrees with respect to the perpendicular direction and be converted into left-circularly polarized light \textcircled{7}. When the vertical linear polarized light \textcircled{2} that has passed through the first polarizing film 812 passes through the second phase retardation film 813, the light may pass through the second phase retardation film 813, which has the first optical axis tilted by about-45 degrees with respect to the perpendicular direction, in the third direction DR3 and thus be converted into the left-circularly polarized light \textcircled{3}, and on the other hand, the vertical linear polarized light \textcircled{6} reflected from the second polarizing film 825 may pass through the third phase retardation film 824, which has the second optical axis tilted by about +45 degrees with respect to the perpendicular direction, in a direction opposite to the third direction DR3 and thus be converted into left-circularly polarized light \textcircled{7}.

The left-circularly polarized light \textcircled{7} that has passed through the third phase retardation film 824 may pass through the first lens DBL and the image thereof may be magnified. The left-circularly polarized light \textcircled{7} that has passed through the first lens DBL may have the same polarization state as the left-circularly polarized light \textcircled{7} that has passed through the third phase retardation film 824 without a change in the polarization state.

Part of the left-circularly polarized light \textcircled{7} that has passed through the first lens DBL may be reflected by the semi-transmissive reflective film 821 and be converted into right-circularly polarized light \textcircled{8} by the left and right inversion effect.

The right-circularly polarized light \textcircled{8} reflected from the semi-transmissive reflective film 821 may pass through the first lens DBL, and the image thereof may be magnified. The right-circularly polarized light \textcircled{8} that has passed through the first lens DBL may have the same polarization state as the right-circularly polarized light \textcircled{8} reflected from the semi-transmissive reflective film 821 without a change in the polarization state.

The right-circularly polarized light \textcircled{8} that has passed through the first lens DBL may pass through the third phase retardation film 824 with the second optical axis tilted by about +45 degrees and be converted into horizontal linear polarized light \textcircled{9}.

Since the horizontal linear polarized light \textcircled{9} that has passed through the third phase retardation film 824 may be light polarized in the same direction as the second polarization axis in the horizontal direction, this light may pass through the second polarizing film 825. The horizontal linear polarized light \textcircled{9} that has passed through the second polarizing film 825 may have the same polarization state as the horizontal linear polarized light \textcircled{9} that has passed through the third phase retardation film 824 without a change in the polarization state.

The horizontal linear polarized light \textcircled{9} that has passed through the second polarizing film 825 may pass through the second lens 831, and the image thereof may be magnified. Horizontal linear polarized light \textcircled{10} that has passed through the second lens 831 may have the same polarization state as the horizontal linear polarized light \textcircled{9} that has passed through the second polarizing film 825 without a change in the polarization state. The horizontal linear polarized light \textcircled{10} that has passed through the second lens 831 may be provided to the user.

In some embodiments, light emitted from the display panel 100 may be polarized light. For example, the display panel may include the first polarizing film 812. In another example, the display panel 100 may emit polarized light and may omit the first polarizing film 812. For example, the display panel 100 may be a OLED display configured to emit polarized light.

In a case where the light emitted from the display panel 100 is polarized light, the polarized light may vibrate in the perpendicular direction and may pass through the second phase retardation film 813 with the first optical axis tilted by about −45 degrees with respect to the perpendicular direction and be converted into left-circularly polarized light \textcircled{3}.

Since the display device 10 according to an embodiment includes folded optics system, light passes through two lenses (or three sub-lenses) a total of four times (or a total of seven times), and the frequency at which the image thereof is magnified may be increased, and the degree to which the image thereof is magnified may increase because the optical path may be increased. Accordingly, the thickness of the display device 10 may be reduced, and a more magnified image may be acquired.

Hereinafter, embodiments of the display device are described. In the following disclosure, description of the same components as those of described above, which are denoted by like reference numerals, may be omitted or simplified, and differences will be mainly described.

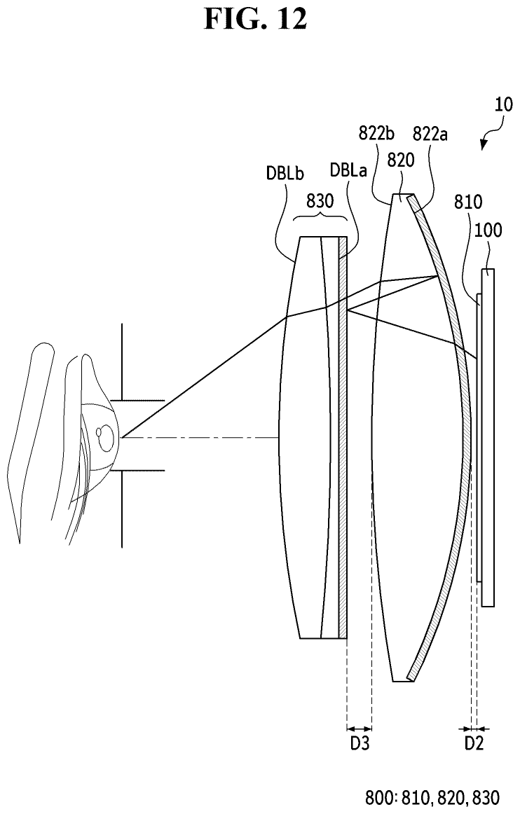

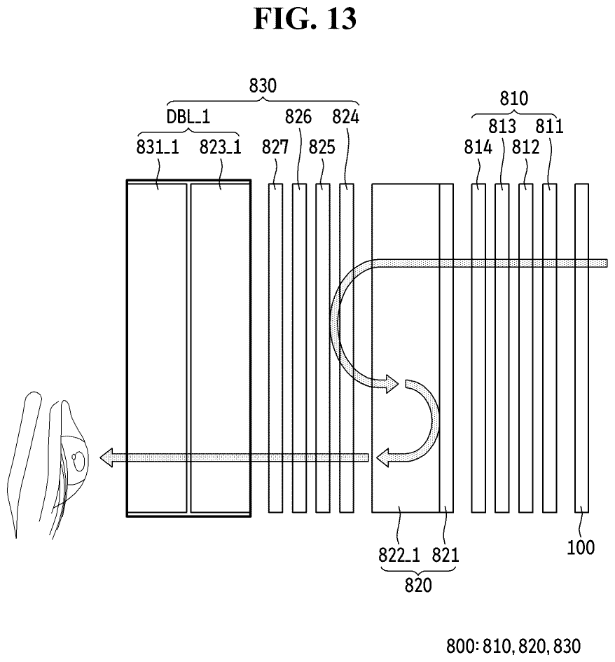

FIG. 12 and FIG. 13 are cross-sectional views showing a display device according to another embodiment.

Referring to FIG. 12 and FIG. 13, in the display device 10 according to an embodiment, the third optical module 830 may include a doublet lens.

More specifically, the first optical module 810 may include the first phase retardation film 811, the first polarizing film 812, the second phase retardation film 813, and the first coating film 814. The second optical module 820 may include the semi-transmissive reflective film 821 and a first lens 822_1. The third optical module 830 may include the third phase retardation film 824, the second polarizing film 825, the third polarizing film 826, the second coating film 827, and a second lens DBL_1. The second lens DBL_1 of the third optical module 830 may include a first sub-lens 831_1 and a second sub-lens 823_1.

The description of the first phase retardation film 811, the first polarizing film 812, the second phase retardation film 813, and the first coating film 814 of the first optical module 810 and the semi-transmissive reflective film 821 of the second optical module 820 is the same as the description of each component of the display device 10 with reference to FIG. 9 and the like, and thus a repeated description thereof may be omitted. In addition, the descriptions of the third phase retardation film 824, the second polarizing film 825, the third polarizing film 826, and the second coating film 827 of the third optical module 830 may be respectively the same as the descriptions of the third phase retardation film 824, the second polarizing film 825, the third polarizing film 826, and the second coating film 827 of the display device 10 described with reference to FIG. 9 and the like, and thus may be omitted.

The first lens 822_1 may be disposed on the first optical module 810. For example, the first lens 822_1 may be disposed on the first coating film 814 of the first optical module 810. The first lens 822_1 may be disposed to be spaced apart from the first optical module 810. The first lens 822_1 may magnify an image formed by light emitted from the display panel 100.

The first lens 822_1 may be a single lens. Lenses of various shapes, such as a convex lens, a meniscus lens, and a Fresnel lens, may be used as the first lens 822_1, and the shape of the first lens 822_1 is not limited.

In some embodiments, the first lens 822_1 may include plastic. For example, the first lens 822_1 may include at least one of polymethylmethacrylate (PMMA)-based plastic or cyclic olefin copolymer (COC)-based plastic.

In some embodiments, the average curvatures of a first surface 822a and a second surface 822b of the first lens 822_1 may be different. For example, the average curvature of the first surface 822a of the first lens 822_1 may be greater than the average curvature of the second surface 822b. In an embodiment, the first surface 822a and the second surface 822b of the first lens 822_1 may be aspherical surfaces including a plurality of curvatures. The first surface 822a of the first lens 822_1 is a surface facing the first optical module 810, and the second surface 822b is a surface facing the third optical module 830. For example, The first surface 822a of the first lens 822_1 is a surface facing the display panel 100, and the second surface 822b is a surface facing away from the display panel 100.

In the display device 10 according to an embodiment, the first lens 822_1 may include an aspherical surface, and the color crosstalk (or color X-talk) phenomenon may be improved. In addition, as described above with reference to FIG. 8, by adjusting the first distance D1 that is the degree to which the plurality of sub-pixels SP1, SP2, and SP3 are shifted with respect to the plurality of lenses LNS in the direction from the middle pixel MPX to the edge pixel EPX and simultaneously adjusting each of the plurality of curvatures of the aspherical surface of the first lens 822_1, the average luminance amount according to the chief ray array (CRA) angle distribution may be further improved.

The second lens DBL_1 may be disposed on the second coating film 827. The second lens DBL_1 may be disposed to be spaced apart from the second optical module 820. The second lens DBL_1 may magnify an image formed by light emitted from the display panel 100.

The second lens DBL_1 may be a doublet lens. For example, the second lens DBL_1 may be a lens in which the first sub-lens 831_1 and the second sub-lens 823_1 may be bonded. An adhesive layer may be disposed between the first sub-lens 831_1 and the second sub-lens 823_1, but the present disclosure is not limited thereto.

In some embodiments, the second lens DBL_1 may include plastic. For example, the second lens DBL_1 may include at least one of polymethylmethacrylate (PMMA)-based plastic, cyclic olefin copolymer (COC)-based plastic, or polycarbonate (PC)-based plastic. The first sub-lens 831_1 and the second sub-lens 823_1 may include different materials. For example, the first sub-lens 831_1 may include at least one of polymethylmethacrylate (PMMA)-based plastic or cyclic olefin copolymer (COC)-based plastic, and the second sub-lens 823_1 may include polycarbonate (PC)-based plastic.

The display device 10 according to an embodiment may reduce the thickness of the optical module 800 by including a doublet lens. Accordingly, a range of distances that the display device 10 may be adjusted to from a user's eyes may be increased, and eye comfort may be ensured. Additionally, the field of view (FOV) may be increased through aberration correction and focus correction by using a doublet lens. Additionally, since the second lens DBL_1 includes plastic, processing of the doublet lens and aspherical surface processing may be facilitated.

In some embodiments, the average curvatures of the first surface DBLa and the second surface DBLb of the second lens DBL_1 may be different. For example, the average curvature of the first surface DBLa of the second lens DBL_1 may be less than the average curvature of the second surface DBLb. In an embodiment, the first surface DBLa of the second lens DBL_1 may be a flat surface, and the second surface DBLb may be an aspherical surface including a plurality of curvatures, but the present disclosure is not limited thereto. The first surface DBLa of the second lens DBL_1 is a surface facing the second optical module 820, and the second surface DBLb is a surface positioned on the opposite side of the first surface DBLa. For example, the first surface DBLa of the second lens DBL_1 is a surface facing the display panel 100, and the second surface DBLb is a surface facing away from the display panel 100.

In the display device 10 according to an embodiment, the second lens DBL_1 may include an aspherical surface, and the color crosstalk (or color X-talk) phenomenon may be improved. In addition, as described above with reference to FIG. 8, by adjusting the first distance D1 that is the degree to which the plurality of sub-pixels SP1, SP2, and SP3 are shifted with respect to the plurality of lenses LNS in the direction from the middle pixel MPX to the edge pixel EPX and simultaneously adjusting each of the plurality of curvatures of the aspherical surface of the second lens DBL_1, the average luminance amount according to the chief ray array (CRA) angle distribution may be further improved.

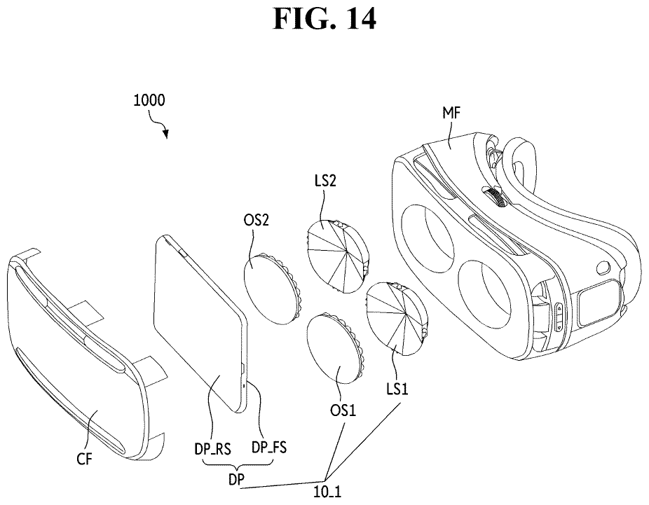

FIG. 14 is an exploded perspective view illustrating a head mounted display according to an embodiment.

Referring to FIG. 14, a head mounted display 1000 is formed in the form of glasses or a head mount to provide an image to a user using a display device 10_1.

The head mounted display 1000 may include a see-through type display that may provide an augmented reality scene to the user based on actual external objects and a see-closed type display that provides a virtual reality scene to the user on a screen, which may be independent from external objects.

The head mounted display 1000 may include a main frame MF mounted on the user's body, the display device 10_1 mounted on the main frame MF to display an image, and a cover frame CF that covers the display device 10_1.

The display device 10_1 may be formed integrally with the head mounted display 1000 that may be carried by the user and easily attached to or detached from a face or a head, and may be formed to be assembled to the head mounted display 1000. The display device 10_1 may be substantially the same as the display device 10 described in conjunction with FIG. 1 and the like.

The display device 10_1 may include a display panel DP that displays an image, first and second lens frames OS1 and OS2 that refract an image display light, and first and second multi-channel lenses LS1 and LS2 that form an optical path and the image display light of the display panel DP may be visible to the user. The display panel DP corresponds to the display panel 100 of FIG. 1.

The main frame MF may be worn on the user's face and/or head. The main frame MF may be formed in a shape corresponding to the user's head and/or facial structure.

The main frame MF may be integrally formed with display device 10_1, that is, the display panel DP, the first and second lens frames OS1 and OS2, and the first and second multi-channel lenses LS1 and LS2. Alternatively, the display panel DP, the first and second lens frames OS1 and OS2, and the first and second multi-channel lenses LS1 and LS2 may be assembled and mounted to the main frame MF. To this end, the main frame MF may have a space or a structure for accommodating the display panel DP, the first and second lens frames OS1 and OS2, and the first and second multi-channel lenses LS1 and LS2. The main frame MF may further include a structure such as a strap or a band to facilitate the mounting, and a controller, an image processing unit, and a lens accommodating unit may be further included in the main frame MF.

The display panel DP may be divided into a front surface DP_FS where an image is displayed, and a rear surface DP_RS located on the opposite side of the front surface DP_FS. Image display light may be emitted from the front surface DP_FS of the display panel DP. As will be described later, the first and second lens frames OS1 and OS2 may be disposed on the front surface DP_FS of the display panel DP, and the first and second multi-channel lenses LS1 and LS2 may be disposed on the front surfaces of the first and second lens frames OS1 and OS2. Meanwhile, at least one infrared camera may be disposed on at least one of the front surface DP_FS or the rear surface DP_RS of the display panel DP. The display panel DP may be substantially the same as the display panel 100 described in conjunction with FIG. 1 and the like.

The display panel DP may be built in the main frame MF in a state where the first and second lens frames OS1 and OS2 and the first and second multi-channel lenses LS1 and LS2 may be mounted and fixed, or may be detachably assembled to the main frame MF. The display panel DP may be opaque, transparent, or translucent depending on the design of the display device 10_1, for example, the usage type of the display device 10_1.

Each of the first and second lens frames OS1 and OS2 may have an area corresponding to the image display surface of the display panel DP, and may be formed in a shape corresponding to that of the image display surface. Further, the first and second lens frames OS1 and OS2 may be formed to have an area and a shape corresponding to those of the rear surfaces of the first and second multi-channel lenses LS1 and LS2, respectively. The rear surfaces of the first and second lens frames OS1 and OS2 may be attached to the image display surface of the display panel DP, and the first and second multi-channel lenses LS1 and LS2 may be attached to the front surfaces of the first and second lens frames OS1 and OS2, respectively. The first and second lens frames OS1 and OS2 refract the image display light emitted from the image display surface of the display panel DP at a preset angle and provide it to the first and second multi-channel lenses LS1 and LS2 disposed on the front surfaces thereof, respectively.

Specifically, the first and second lens frames OS1 and OS2 may refract the image display light, which is emitted from the image display surface of the display panel DP toward the front side, toward an outer side (or toward an outer peripheral side) compared to the front side and provide it to the first and second multi-channel lenses LS1 and LS2 disposed on the front surfaces thereof, respectively. In particular, the first and second lens frames OS1 and OS2 may refract the image display light incident on the rear surfaces thereof toward the outer side (or toward the outer peripheral side) and provide it to the rear surfaces of the first and second multi-channel lenses LS1 and LS2, respectively.

The first and second multi-channel lenses LS1 and LS2 may form a path for light emitted through the first and second lens frames OS1 and OS2, and the image display light may be visible to the user's eyes on the front side.

The first and second multi-channel lenses LS1 and LS2 may provide a plurality of channels (or paths) through which the image display light emitted from the display panel DP passes. The plurality of channels may provide the image display light emitted from the display panel DP to the user through different paths. The image display light emitted through the first and second lens frames OS1 and OS2 may be incident on the respective channels, and the image magnified through the respective channels may be focused on the user's eyes.

The first and second multi-channel lenses LS1 and LS2 may be respectively disposed on the front surfaces the first and second lens frames OS1 and OS2 to correspond to the positions of the user's left eye and right eye. The first and second multi-channel lenses LS1 and LS2 may be accommodated in the main frame MF.

The first and second multi-channel lenses LS1 and LS2 may refract and/or reflect the image display light emitted through the first and second lens frames OS1 and OS2 at least once to form a path to the user's eyes. At least one infrared light source may be further disposed at the main frame MF, or on a side of each of the first and second multi-channel lenses LS1 and LS2 facing the user's eyes.

The cover frame CF may be disposed on the rear surface DP_RS of the display panel DP to cover the display panel DP and may protect the display panel DP. The cover frame CF may be attached to the main frame MF while covering the display panel DP.

In some embodiments, the display device 10_1 may further include a controller for controlling the overall operation of the display device 10_1 including the display panel DP. The controller may control the image display operation of the display panel DP and audio devices. Specifically, the controller performs image processing (e.g., image mapping) according to the magnification ratio and the image display path corresponding to the first and second lens frames OS1 and OS2 and the first and second multi-channel lenses LS1 and LS2, and controls the mapped image to be displayed on the display panel DP. The controller may be implemented as a dedicated processor including an embedded processor and/or a general-purpose processor including a central processing unit or an application processor, but is not limited thereto.

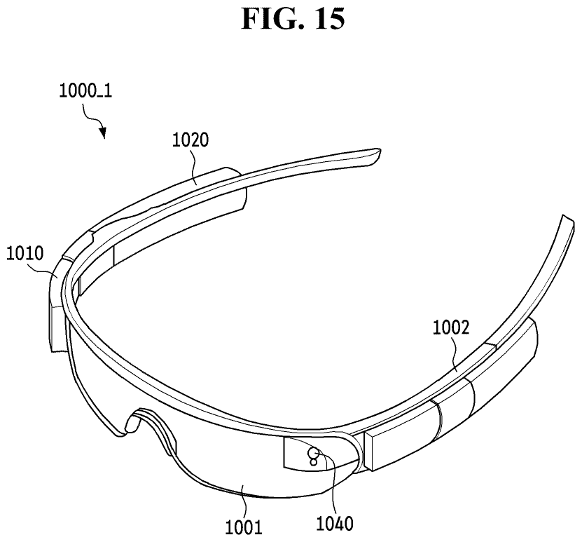

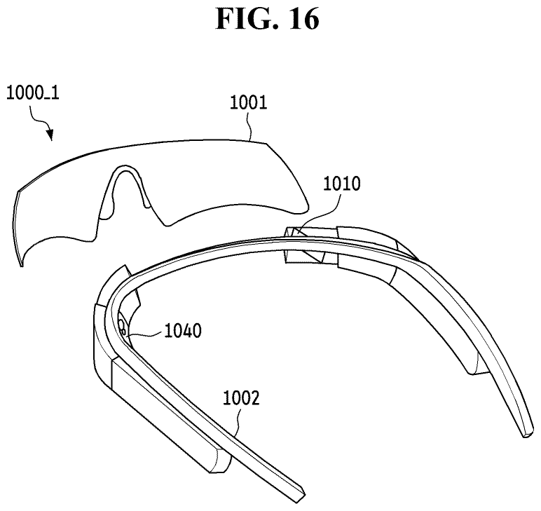

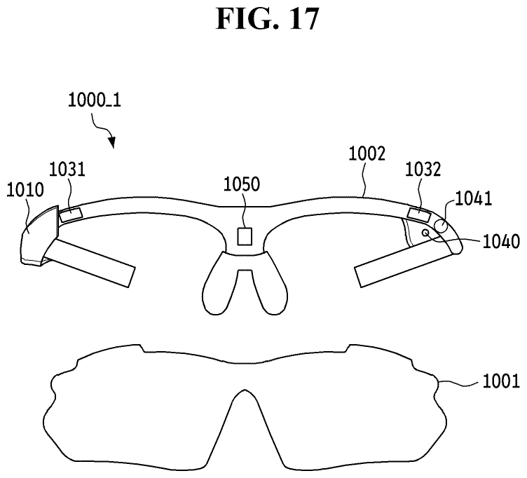

FIG. 15 is a perspective view showing an augmented reality content providing device according to an embodiment. FIG. 16 is a rear exploded perspective view of the augmented reality content providing device of FIG. 15. FIG. 17 is a front exploded perspective view of the augmented reality content providing device of FIG. 15.

Referring to FIGS. 15 to 17, an augmented reality content providing device 1000_1 may include a support frame 1002 supporting at least one transparent lens 1001, at least one image display module 1010, a surrounding environment detector 1040, and a control module 1020.

The support frame 1002 may be formed in the form of glasses including a spectacle frame supporting the edge of at least one transparent lens 1001 and spectacle frame legs. The shape of the support frame 1002 is not limited to a glasses type, and may be formed in a goggle type including the transparent lens 1001, or a head mount type.

The transparent lens 1001 may include left and right parts formed integrally, or first and second transparent lenses formed separately. The transparent lens 1001, which includes the integrated left and right parts or the separated first and second transparent lenses, may be made of glass or plastic that is transparent or translucent. Accordingly, the user can view the image of reality through the transparent lens 1001 that includes the integrated right and left parts or the separated first and second transparent lenses. Here, the transparent lens 1001, that is, the integrated lens or the first and second transparent lenses, may have a refractive power in consideration of the user's eyesight.

The transparent lens 1001 may further include at least one reflective member that reflects the augmented reality content image provided from the at least one image display module 1010 toward the transparent lens 1001 or the user's eyes, and optical members that adjust a focus and a size. One or more reflective member may be built in the transparent lens 1001 to be integrated with the transparent lens 1001, and may be formed as a plurality of refractive lenses or a plurality of prisms with a predetermined curvature.

The at least one image display module 1010 may include a micro LED display device (micro-LED), a nano LED display device (nano-LED), an organic light-emitting display device (OLED), an inorganic light-emitting display device (inorganic EL), a quantum dot light-emitting display device (QED), a cathode ray display (CRT), a liquid crystal display (LCD), or the like. The image display module 1010 may substantially include the display device 10 described with reference to FIG. 1 and the like.

The surrounding environment detector 1040 is assembled or integrally formed with the support frame 1002, and detects the distance (or depth) to an object on the front side of the support frame 1002, the illuminance, the moving direction of the support frame 1002, the moving distance, the tilt, or the like. To this end, the surrounding environment detector 1040 includes a depth sensor 1041 such as an infrared sensor or a LiDAR sensor, and an image sensor 1050 such as a camera. Further, the surrounding environment detector 1040 may further include at least one motion sensor among an illumination sensor, a human body detection sensor, a gyro sensor, a tilt sensor, and an acceleration sensor. Further, the surrounding environment detector 1040 may further include first and second biometric sensors 1031 and 1032 for detecting movement information of the user's eyes or pupils.

The surrounding environment detector 1040 may transmit sensing signals generated by the depth sensor 1041 and at least one motion sensor to the control module 1020 in real time. Further, the image sensor 1050 may transmit image data in units of at least one frame generated in real time to the control module 1020. The first and second biometric sensors 1031 and 1032 of the surrounding environment detector 1040 may transmit the detected pupil detection signals to the control module 1020.

The control module 1020 may be assembled to at least one side of the support frame 1002 together with the at least one image display module 1010 or may be formed integrally with the support frame 1002. The control module 1020 may supply augmented reality content data to the at least one image display module 1010 and the at least one image display module 1010 may display augmented reality content, e.g., an augmented reality content image. At the same time, the control module 1020 may receive sensing signals, image data, and pupil detection signals from the surrounding environment detector 1040 in real time.

In concluding the detailed description, those skilled in the art will appreciate that many variations and modifications can be made to the preferred embodiments without substantially departing from the principles of the present disclosure. Therefore, embodiments of the invention are used in a generic and descriptive sense only and not for purposes of limitation.

What is claimed is:

1. A display device comprising:
a display panel configured to emit polarized light;
a first phase retardation film disposed on the display panel;
a semi-transmissive reflective film disposed on the first phase retardation film;
a first lens disposed on the semi-transmissive reflective film;
a second phase retardation film disposed on the first lens;
a first polarizing film disposed on the second phase retardation film; and
a second lens disposed on the first polarizing film,
wherein the first lens or the second lens is a doublet lens in which a first sub-lens and a second sub-lens are bonded.

2. The display device of claim 1, wherein
the first lens is the doublet lens,
the first lens comprises a first surface facing the display panel and a second surface facing away from the display panel, and
average curvatures of the first surface and the second surface are different.

3. The display device of claim 1, wherein
the second lens is the doublet lens,
the second lens comprises a first surface facing the display panel and a second surface facing away from the display panel, and
average curvatures of the first surface and the second surface are different.

4. A display device comprising:
a display panel;
a first polarizing film disposed on the display panel;
a first phase retardation film disposed on the first polarizing film;
a semi-transmissive reflective film disposed on the first phase retardation film;
a first lens disposed on the semi-transmissive reflective film;
a second phase retardation film disposed on the first lens;
a second polarizing film disposed on the second phase retardation film; and
a second lens disposed on the second polarizing film,
wherein the first lens or the second lens is a doublet lens in which a first sub-lens and a second sub-lens are bonded.

5. The display device of claim 4, wherein
the first lens is the doublet lens,
the first lens comprises a first surface facing the display panel and a second surface facing away from the display panel, and
average curvatures of the first surface and the second surface are different.

6. The display device of claim 5, wherein the average curvature of the first surface is greater than the average curvature of the second surface.

7. The display device of claim 6, wherein the first surface is an aspherical surface, and the second surface is a flat surface.

8. The display device of claim 4, wherein
the first lens is the doublet lens,
the second lens comprises a third surface facing the display panel and a fourth surface facing away from the display panel, and
average curvatures of the third surface and the fourth surface are different.

9. The display device of claim 8, wherein the average curvature of the third surface is less than the average curvature of the fourth surface.

10. The display device of claim 9, wherein the third surface and the fourth surface are aspherical surfaces.

11. The display device of claim 4, wherein the first lens and the second lens contain plastic.

12. The display device of claim 4, wherein
the first lens is the doublet lens,
the first sub-lens contains at least one of polymethylmethacrylate (PMMA)-based plastic or cyclic olefin copolymer (COC)-based plastic,
the second sub-lens contains polycarbonate (PC)-based plastic, and
the second lens contains at least one of polymethylmethacrylate (PMMA)-based plastic or cyclic olefin copolymer (COC)-based plastic.

13. The display device of claim 4, wherein
the second lens is the doublet lens,
the first lens contains at least one of polymethylmethacrylate (PMMA)-based plastic or cyclic olefin copolymer (COC)-based plastic,
the first sub-lens contains polycarbonate (PC)-based plastic, and
the second sub-lens contains at least one of polymethylmethacrylate (PMMA)-based plastic or cyclic olefin copolymer (COC)-based plastic.

14. The display device of claim 4, wherein
the display panel comprises a plurality of pixels, a display element layer, and a plurality of lenses disposed on the display element layer and corresponding to the plurality of pixels,
among the plurality of pixels, pixels positioned in a middle portion of the display panel are disposed in a straight line with corresponding first lenses of the plurality of lenses, and
among the plurality of pixels, pixels positioned at an edge portion of the display panel are disposed to be shifted by a distance from corresponding second lenses of the plurality of lenses.

15. The display device of claim 4, wherein
the second lens is the doublet lens,
the second lens comprises a first surface facing the display panel and a second surface facing away from the display panel, and
average curvatures of the first surface and the second surface are different.

16. The display device of claim 15, wherein
the second lens is the doublet lens,
the average curvature of the first surface is less than the average curvature of the second surface.

17. The display device of claim 16, wherein the first surface is a flat surface, and the second surface is an aspherical surface.

18. The display device of claim 4, wherein
the second lens is the doublet lens,
the first lens comprises a third surface facing the display panel and a fourth surface facing away from the display panel, and
average curvatures of the third surface and the fourth surface are different.

19. The display device of claim 18, wherein the average curvature of the third surface is greater than the average curvature of the fourth surface.

20. An electronic device comprise a display device, the display device comprising:
a display panel;
a first polarizing film disposed on the display panel;
a first phase retardation film disposed on the first polarizing film;
a semi-transmissive reflective film disposed on the first phase retardation film;
a first lens disposed on the semi-transmissive reflective film;
a second phase retardation film disposed on the first lens;
a second polarizing film disposed on the second phase retardation film; and
a second lens disposed on the second polarizing film,
wherein the first lens or the second lens is a doublet lens in which a first sub-lens and a second sub-lens are bonded.
